(19) United States
(12) Patent Application Publication
(10) Pub. No.: US 2026/0173619 A1
(43) Pub. Date: Jun. 18, 2026

(54) ARRAY SUBSTRATE AND DISPLAY PANEL

(71) Applicants: HEFEI VISIONOX TECHNOLOGY CO., LTD., Hefei (CN); HEFEI VISIONOX ELECTRONICS CO., LTD., Hefei (CN); VISIONOX TECHNOLOGY INC., Jiangsu (CN)

(72) Inventors: Zhiwei ZHOU, Hefei (CN); Yang YANG, Hefei (CN); Jinfang ZHANG, Hefei (CN); Aihua XUE, Hefei (CN); Lu ZHANG, Hefei (CN)

(73) Assignees: HEFEI VISIONOX TECHNOLOGY CO., LTD., Hefei (CN); HEFEI VISIONOX ELECTRONICS CO., LTD., Hefei (CN); VISIONOX TECHNOLOGY INC., Jiangsu (CN)

(21) Appl. No.: 19/434,309

(22) Filed: Dec. 29, 2025

Related U.S. Application Data
(63) Continuation of application No. PCT/CN2025/134136, filed on Nov. 11, 2025.

(30) Foreign Application Priority Data
Dec. 13, 2024 (CN) 202411847159.7

(51) Int. Cl. H10H 29/49; H10H 29/37; H10H 29/39; H10H 29/855

(52) U.S. Cl. CPC H10H 29/49; H10H 29/37; H10H 29/39; H10H 29/855

(57) ABSTRACT

An array substrate and a display panel. The array substrate includes a base, a signal line layer group, and a first electrode layer. The signal line layer group includes a plurality of non-constant signal lines and a plurality of constant signal lines. The first electrode layer is located on a side of the signal line layer group away from the base, and the first electrode layer includes a pixel electrode. An overlapping area between an orthographic projection of the non-constant signal line and an orthographic projection of the pixel electrode on the base is less than an overlapping area between an orthographic projection of the constant signal line and the orthographic projection of the same one of the pixel electrodes on the base.

### CROSS REFERENCE TO RELATED APPLICATIONS

This application is a continuation of International Application No. PCT/CN2025/134136, filed on Nov. 11, 2025, which claims priority to Chinese Patent Application No. 202411847159.7, entitled “ARRAY SUBSTRATE AND DISPLAY PANEL”, filed on Dec. 13, 2024, both of which are incorporated herein by reference in their entireties.

### FIELD

The present application relates to the field of display, and in particular, to an array substrate and a display panel.

### BACKGROUND

Flat display panels such as Organic Light Emitting Display (OLED) panels and display panels utilizing Light Emitting Diode (LED) devices are widely used in various consumer electronic products such as mobile phones, televisions, personal digital assistants, digital cameras, notebook computers, and desktop computers due to their advantages of high image quality, low power consumption, thin profile, and wide application range, becoming mainstream in display devices. In the traditional display panel manufacturing process, light-emitting pixels are typically patterned using Fine Metal Masks (FMM). FMM technology is mature and has extensive mass production experience. However, FMM technology also has issues such as limited precision, high development costs, and long development cycles. Mask-free fine metal technology eliminates the limitations of traditional OLED processes on display size, resolution, and other screen performance, offering advantages such as high performance, full-size capability, and agile delivery. Patents CN118251982A, CN116648095A, CN117062489A, CN118742138A, CN118678783A, CN118660598A, CN118675450A, CN118824188A, and CN118781966A document related content of mask-free fine metal technology for reference.

### SUMMARY

Embodiments of the present application provide an array substrate and a display panel.

In a first aspect, an embodiment of the present application provides an array substrate. The array substrate includes a base, a signal line layer group, and a first electrode layer. The signal line layer group is located on a side of the base, and the signal line layer group includes a plurality of non-constant signal lines and a plurality of constant signal lines. The first electrode layer is located on a side of the signal line layer group away from the base, and the first electrode layer includes a plurality of pixel electrodes. An overlapping area between an orthographic projection of the non-constant signal line and an orthographic projection of one of the pixel electrodes on the base is less than an overlapping area between an orthographic projection of the constant signal line and the orthographic projection of the same one of the pixel electrode on the base.

In a second aspect, an embodiment of the present application provides an array substrate. The array substrate includes a base, a signal line layer group, and a first electrode layer. The signal line layer group is located on a side of the base, the signal line layer group includes a non-constant signal line and a constant signal line, and both the non-constant signal line and the constant signal line extend along a first direction. The first electrode layer is located on a side of the signal line layer group away from the base, and the first electrode layer includes a plurality of pixel electrodes. In a second direction intersecting the first direction, at least a portion of an orthographic projection of the constant signal line on the base is located within an orthographic projection of one of the pixel electrodes on the base, and at least a portion of an orthographic projection of an edge of the constant signal line away from a centroid of the pixel electrode on the base is located within the orthographic projection of the corresponding pixel electrode on the base.

In a third aspect, an embodiment of the present application provides a display panel, including the array substrate according to any of the preceding embodiments and a light-emitting layer. The light-emitting layer is located on a side of the array substrate, the light-emitting layer includes a light-emitting unit, and an orthographic projection of the light-emitting unit on the base at least partially overlaps with the orthographic projection of the pixel electrode on the base.

### BRIEF DESCRIPTION OF THE DRAWINGS

In order to more clearly illustrate the technical solutions of the embodiments of the present application, the following will briefly introduce the drawings required for describing the embodiments. For those skilled in the art, other drawings may also be obtained based on these drawings without creative effort.

FIG. 1 is a schematic cross-sectional structural view of an array substrate according to an embodiment of the present application.

FIG. 2 is a partially enlarged schematic structural view of an array substrate according to an embodiment of the present application.

FIG. 3 is a partially enlarged schematic structural view of a first electrode layer in an array substrate according to an embodiment of the present application.

FIG. 4 is a partially enlarged schematic structural view of a signal line layer group in an array substrate according to an embodiment of the present application.

FIG. 5 is a partially enlarged schematic structural view of another array substrate according to an embodiment of the present application.

FIG. 6 is a partially enlarged schematic structural view of a first electrode layer in another array substrate according to an embodiment of the present application.

FIG. 7 is a partially enlarged schematic structural view of another array substrate according to an embodiment of the present application.

FIG. 8 is a partially enlarged schematic structural view of another array substrate according to an embodiment of the present application.

FIG. 9 is a partially enlarged schematic structural view of another array substrate according to an embodiment of the present application.

FIG. 10 is a partially enlarged schematic structural view of another array substrate according to an embodiment of the present application.

FIG. 11 is a schematic cross-sectional structural view of another array substrate according to an embodiment of the present application.

FIG. 12 is a schematic cross-sectional structural view of another array substrate according to an embodiment of the present application.

FIG. 13 is a schematic cross-sectional structural view of another array substrate according to an embodiment of the present application.

FIG. 14 is a schematic cross-sectional structural view of another array substrate according to an embodiment of the present application.

FIG. 15 is a schematic cross-sectional structural view of a display panel according to an embodiment of the present application.

FIG. 16 is a schematic cross-sectional structural view of another display panel according to an embodiment of the present application.

FIG. 17 is a schematic cross-sectional structural view of another display panel according to an embodiment of the present application.

### REFERENCE NUMERALS

100: array substrate; 200: display panel;
10: base; 20: signal line layer group; 21: non-constant signal line; 211: first non-constant signal line; 211a: first segment; 211b: second segment; 211c: third segment;
22: constant signal line; 221: first constant signal line; 221a: surface signal portion;
221b: connection portion; 221b1: first connection portion; 221b2: second connection portion; 222: second constant signal line; 223: first portion; 224: second portion; K1: via; L1: first edge; L2: second edge; E1: shielding structure;
30: first electrode layer; 31: pixel electrode; 311: first electrode; 312: second electrode;
313: third electrode; 40: thin film transistor; Q: virtual quadrilateral; Q 1: first virtual quadrilateral; Q2: second virtual quadrilateral;
50: electrode connection portion; 51: first electrode connection portion; 52: second electrode connection portion; 53: third electrode connection portion; 60: isolation structure; 61: first isolation portion; 62: second isolation portion; 63: isolation opening; 64: first opening; 65: third isolation portion; 70: light-emitting unit; 80: second electrode layer; 90: pixel definition layer; X: first direction; Y: second direction; Z: thickness direction.

### DETAILED DESCRIPTION

The features and exemplary embodiments of various aspects of the present application will be described in detail below. In order to make the purposes, technical solutions, and advantages of the present application clearer, the following further describes the present application in detail with reference to the accompanying drawings and specific embodiments. It should be understood that the specific embodiments described herein are only intended to explain the present application and not to limit it. For those skilled in the art, the present application can be implemented without some of these specific details. The description of the embodiments below is merely intended to provide a better understanding of the present application by illustrating examples of the present application.

It should be noted that in this application, relational terms such as first and second are used merely to distinguish one entity or operation from another entity or operation, without necessarily requiring or implying any such actual relationship or order between these entities or operations. Furthermore, the terms “include”, “comprise”, or any other variations thereof are intended to cover non-exclusive inclusion, such that a process, method, article, or device that includes a series of elements includes not only those elements but also other elements not explicitly listed, or elements inherent to such process, method, article, or device. Without further limitation, an element defined by the phrase “including a . . . ” does not exclude the presence of additional identical elements in the process, method, article, or device that includes the element.

In related array substrates, various circuits are arranged on the array substrate to drive the display and other functions of the display panel. In the circuits of the array substrate, parasitic capacitances exist between different conductive layers. Under the condition that two conductive layers are adjacent, a capacitor is formed between them. If the voltage of one conductive layer changes, it can affect the voltage of the other conductive layer through capacitive coupling. For example, in the array substrate, with the electrode configured to drive light emission and the non-constant signal line below the electrode, under the condition that the electrode and the non-constant signal line overlap, the non-constant signal line will output a voltage or current that changes over time based on control requirements, causing the voltage of the electrode during normal operation to be affected by the non-constant signal line, resulting in capacitive coupling crosstalk problems, which in turn cause display abnormalities in the display panel.

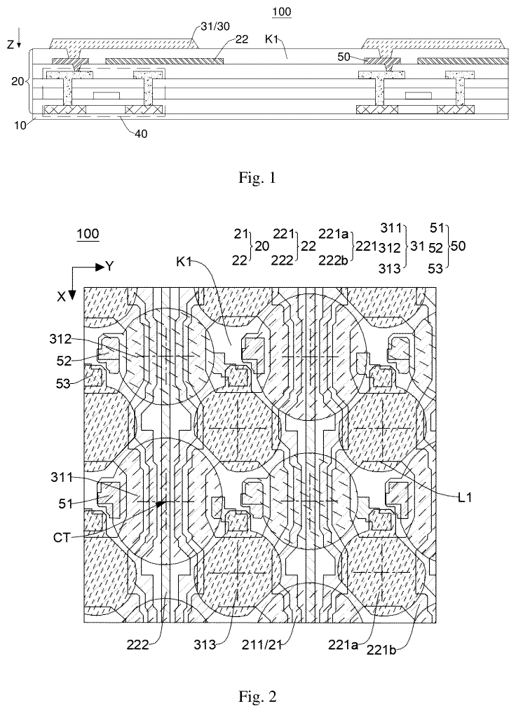

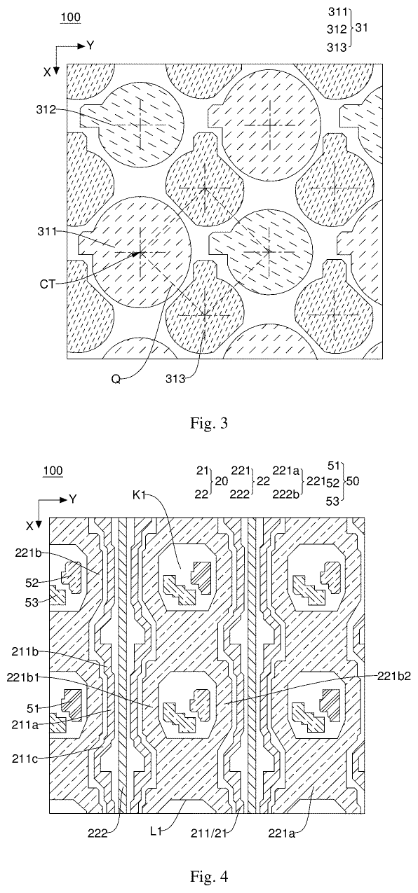

FIG. 1 is a schematic cross-sectional structural view of an array substrate according to an embodiment of the present application. FIG. 2 is a partially enlarged schematic structural view of an array substrate according to an embodiment of the present application. FIG. 3 is a partially enlarged schematic structural view of a first electrode layer in an array substrate according to an embodiment of the present application. FIG. 4 is a partially enlarged schematic structural view of a signal line layer group in an array substrate according to an embodiment of the present application.

In view of this, in a first aspect, referring to FIG. 1 to FIG. 4, an embodiment of the present application provides an array substrate 100. The array substrate 100 includes a base 10, a signal line layer group 20, and a first electrode layer 30. The signal line layer group 20 is located on a side of the base 10, and the signal line layer group 20 includes a plurality of non-constant signal lines 21 and a plurality of constant signal lines 22. The first electrode layer 30 is located on a side of the signal line layer group 20 away from the base 10, and the first electrode layer 30 includes a plurality of pixel electrodes 31. An overlapping area between an orthographic projection of the non-constant signal line 21 and an orthographic projection of one of the pixel electrodes 31 on the base 10 is less than an overlapping area between an orthographic projection of the constant signal line 22 and the orthographic projection of said pixel electrode 31 on the base 10.

In some embodiments, the base 10 primarily serves a support and carrying function, and other film layers are sequentially stacked on the base 10. The term “stacked” mentioned here means that other film layers are stacked along the thickness direction Z of the base 10. The base 10 may include a single or multiple film layer structures, and the specific film layer structure composition of the base 10 is not limited in the embodiments of the present application. Furthermore, the thickness direction Z of other film layers located on one side of the base 10 is usually consistent with the thickness direction Z of the base 10 itself. Therefore, for convenience of description, the thickness direction Z of the base 10 or other film layers mentioned subsequently in the embodiments of the present application is indicated by the same direction. The base 10 may be a rigid base 10, for example, including a glass base 10. Alternatively, the base 10 may be a flexible base 10, for example, including organic materials such as polyimide.

The signal line layer group 20 may include one or more layers. For example, under the condition that the signal line layer group 20 includes multiple layers, the multiple layers in the signal line layer group 20 are stacked sequentially along a direction away from the base 10. Optionally, the non-constant signal line 21 and the constant signal line 22 may be located in the same layer or in different layers. It is obvious that under the condition that the signal line layer group 20 includes multiple layers, one layer may include both the constant signal line 22 and the non-constant signal line 21, another layer may only include the non-constant signal line 21, and yet another layer may only include the constant signal line 22.

The non-constant signal line 21 refers to a wire that transmits signals whose voltage or current changes over time in the array substrate 100. These signals are typically configured to control various functions of the display panel. Optionally, the number of non-constant signal lines 21 includes one or more. The types of non-constant signal lines 21 include one or more, for example, the non-constant signal line 21 includes a data line for implementing pixel data transmission, a scan line for controlling the switching state of pixels, a power line for transmitting a dynamically adjusted supply voltage, a clock signal line for transmitting clock signals, and so on.

The constant signal line 22 refers to a wire that transmits signals whose voltage or current remains unchanged in the array substrate 100. These signals are typically configured to provide a stable reference voltage or current to ensure that various parts of the display panel can work normally. Optionally, the number of constant signal lines 22 includes one or more. The types of constant signal lines 22 include one or more, for example, the constant signal line 22 includes a reference voltage line for providing a stable reference voltage, a ground line for providing a stable ground potential, a power line for transmitting a stable power supply voltage, and so on. Optionally, the power line may include a first power line for transmitting a power supply voltage to an anode and a second power line for transmitting a power supply voltage to a cathode.

The first electrode layer 30 is located on a side of the signal line layer group 20 away from the base 10. The first electrode layer 30 includes a plurality of pixel electrodes 31, and the plurality of pixel electrodes 31 are spaced apart. Optionally, the plurality of pixel electrodes 31 may be arranged in one-to-one correspondence with light-emitting units 70 in the display panel. Optionally, the pixel electrode 31 may be an anode or a cathode.

In some embodiments, the non-constant signal line 21 and the constant signal line 22 may be wires extending along a single direction on the array substrate 100. An orthographic projection of one non-constant signal line 21 on the base 10 may overlap with each of orthographic projections of a plurality of pixel electrodes 31 on the base 10. Similarly, an orthographic projection of one constant signal line 22 on the base 10 may overlap with each of orthographic projections of a plurality of pixel electrodes 31 on the base 10.

Optionally, an orthographic projection of one pixel electrode 31 on the base 10 may overlap with an orthographic projection of one or more non-constant signal lines 21 on the base 10.

Optionally, an orthographic projection of one pixel electrode 31 on the base 10 may overlap with an orthographic projection of one or more constant signal lines 22 on the base 10.

Under the condition that an orthographic projection of one pixel electrode 31 on the base 10 overlaps with an orthographic projection of one non-constant signal line 21 on the base 10, the area of the overlapping region between the orthographic projection of the pixel electrode 31 on the base 10 and the orthographic projection of the non-constant signal line 21 on the base 10 is the overlapping area between the non-constant signal line 21 and the pixel electrode 31 on the base 10. Under the condition that an orthographic projection of one pixel electrode 31 on the base 10 overlaps with orthographic projections of a plurality of non-constant signal lines 21 on the base 10, the sum of the areas of the overlapping regions between the orthographic projection of the pixel electrode 31 on the base 10 and the orthographic projections of the plurality of non-constant signal lines 21 on the base 10 is the overlapping area between the non-constant signal lines 21 and the pixel electrode 31 on the base 10.

Under the condition that an orthographic projection of one pixel electrode 31 on the base 10 overlaps with an orthographic projection of one constant signal line 22 on the base 10, the area of the overlapping region between the orthographic projection of the pixel electrode 31 on the base 10 and the orthographic projection of the constant signal line 22 on the base 10 is the overlapping area between the constant signal line 22 and the pixel electrode 31 on the base 10. Under the condition that an orthographic projection of one pixel electrode 31 on the base 10 overlaps with orthographic projections of a plurality of constant signal lines 22 on the base 10, the sum of the areas of the overlapping regions between the orthographic projection of the pixel electrode 31 on the base 10 and the orthographic projections of the plurality of constant signal lines 22 on the base 10 is the overlapping area between the constant signal lines 22 and the pixel electrode 31 on the base 10.

The overlapping area between the non-constant signal line 21 and the pixel electrode 31 on the base 10 may refer to the overlapping area between the orthographic projection of one pixel electrode 31 on the base 10 and the orthographic projection of the non-constant signal line 21 on the base 10, or it may refer to the overlapping area between the orthographic projections of all pixel electrodes 31 on the base 10 and the orthographic projection of the non-constant signal on the base 10.

The overlapping area between the constant signal line 22 and the pixel electrode 31 on the base 10 may refer to the overlapping area between the orthographic projection of one pixel electrode 31 on the base 10 and the orthographic projection of the constant signal line 22 on the base 10, or it may refer to the overlapping area between the orthographic projections of all pixel electrodes 31 on the base 10 and the orthographic projection of the constant signal on the base 10.

It can be understood that under the condition that the overlapping area between the non-constant signal line 21 and the pixel electrode 31 on the base 10 refers to the overlapping area between the orthographic projection of one pixel electrode 31 on the base 10 and the orthographic projection of the non-constant signal line 21 on the base 10, and the overlapping area between the constant signal line 22 and the pixel electrode 31 on the base 10 refers to the overlapping area between the orthographic projection of one pixel electrode 31 on the base 10 and the orthographic projection of the constant signal line 22 on the base 10, then the statement that the overlapping area between the non-constant signal line 21 and the pixel electrode 31 on the base 10 is less than the overlapping area between the constant signal line 22 and the pixel electrode 31 on the base 10 means that for the same pixel electrode 31, the overlapping area between the non-constant signal line 21 and the pixel electrode 31 on the base 10 is less than the overlapping area between the constant signal line 22 and the pixel electrode 31 on the base 10.

The embodiment of the present application provides an array substrate 100. By making the overlapping area between the non-constant signal line 21 and the pixel electrode 31 on the base 10 less than the overlapping area between the constant signal line 22 and the pixel electrode 31 on the base 10, the capacitive coupling between the non-constant signal line 21 and the pixel electrode 31 is reduced, thereby reducing the impact of voltage or current changes in the non-constant signal line 21 on the voltage in the pixel electrode 31 through coupling effects, reducing the possibility of voltage changes in the pixel electrode 31, increasing the capacitive coupling between the constant signal line 22 and the pixel electrode 31, to enhance the influence of the stable voltage in the constant signal line 22 on the voltage in the pixel electrode 31, further reducing the possibility of voltage changes in the pixel electrode 31, lowering the possibility of crosstalk between the pixel electrode 31 and the non-constant signal line 21, improving the reliability of the array substrate 100, and thereby improving the reliability of the display panel.

In some optional embodiments, a ratio of the overlapping area between the non-constant signal line 21 and the pixel electrode 31 on the base 10 to an area of the orthographic projection of the corresponding pixel electrode 31 on the base 10 is S1, and S1≤40%.

The overlapping area between the non-constant signal line 21 and the pixel electrode 31 on the base 10 and the area of the orthographic projection of the corresponding pixel electrode 31 on the base 10 can be understood as, for the same pixel electrode 31, the overlapping area between the non-constant signal line 21 and the pixel electrode 31 on the base 10 and the area of the orthographic projection of said pixel electrode 31 on the base 10.

For example, the ratio of the overlapping area between the non-constant signal line 21 and the pixel electrode 31 on the base 10 to the area of the orthographic projection of the corresponding pixel electrode 31 on the base 10 is 1%, 2%, 3%, 5%, 10%, 15%, 20%, 25%, 30%, 35%, or 40%.

By the above arrangement, the embodiment of the present application is conducive to reducing the overlapping area between the non-constant signal line 21 and the pixel electrode 31, thereby reducing the possibility of crosstalk between the non-constant signal line 21 and the pixel electrode 31.

Optionally, the ratio of the overlapping area between the non-constant signal line 21 and the pixel electrode 31 on the base 10 to the area of the orthographic projection of the corresponding pixel electrode 31 on the base 10 is 5%-35%. Such an arrangement can reduce the possibility of crosstalk between the non-constant signal line 21 and the pixel electrode 31 while also helping to reduce the internal resistance of the non-constant signal line 21 and improve the response speed of the array substrate 100.

In some optional embodiments, a ratio of the overlapping area between the constant signal line 22 and the pixel electrode 31 on the base 10 to an area of the orthographic projection of the corresponding pixel electrode 31 on the base 10 is S2, and S2≥45%.

The overlapping area between the constant signal line 22 and the pixel electrode 31 on the base 10 and the area of the orthographic projection of the corresponding pixel electrode 31 on the base 10 can be understood as, for the same pixel electrode 31, the overlapping area between the constant signal line 22 and the pixel electrode 31 on the base 10 and the area of the orthographic projection of this pixel electrode 31 on the base 10.

For example, the ratio of the overlapping area between the constant signal line 22 and the pixel electrode 31 on the base 10 to the area of the orthographic projection of the corresponding pixel electrode 31 on the base 10 is 45%, 46%, 48%, 50%, 60%, 70%, 80%, 90%, or 100%.

By the above arrangement, the embodiment of the present application is conducive to increasing the overlapping area between the constant signal line 22 and the pixel electrode 31, thereby enhancing the capacitive coupling effect between the constant signal line 22 and the pixel electrode 31, reducing the possibility of abnormal voltage in the pixel electrode 31, improving the reliability of the array substrate 100, and thereby improving the reliability of the display panel.

In some optional embodiments, as shown in FIG. 3, the pixel electrodes 31 include a first electrode 311, a second electrode 312, and a third electrode 313. The first electrode 311, the second electrode 312, and the third electrode 313 are respectively disposed corresponding to light-emitting units 70 of different colors.

The embodiment of the present application does not limit the colors of the light-emitting units 70 corresponding to the first electrode 311, the second electrode 312, and the third electrode 313. For example, the light-emitting units 70 include different colors, such as a red light-emitting unit 70, a green light-emitting unit 70, and a blue light-emitting unit 70. Optionally, the first electrode 311 may correspond to the red light-emitting unit 70, the second electrode 312 may correspond to the blue light-emitting unit 70, and the third electrode 313 may correspond to the green light-emitting unit 70. Optionally, the light-emitting units 70 may further include a white light-emitting unit 70, and one of the first electrode 311, the second electrode 312, and the third electrode 313 may also correspond to the white light-emitting unit 70.

The embodiment of the present application does not limit the shapes and sizes of the first electrode 311, the second electrode 312, and the third electrode 313. For example, the shapes of the first electrode 311, the second electrode 312, and the third electrode 313 may be the same or different, or two of them may be the same, or all three may be different.

By the above arrangement, the embodiment of the present application is conducive to reducing the possibility of crosstalk between the pixel electrodes 31 corresponding to light-emitting units 70 of different colors and the non-constant signal line 21, improving the stability of the display effect of light-emitting units 70 of different colors, and thereby improving the reliability of the display panel.

In some optional embodiments, as shown in FIG. 1 to FIG. 4, centroids of one of the first electrodes 311, one of the second electrodes 312, and two of the third electrodes 313 are respectively disposed at four vertices of a virtual quadrilateral Q.

In other words, the centers of one of the first electrodes 311, one of the second electrodes 312, and two of the third electrodes 313 which are adjacent to each other can be connected to form a virtual quadrilateral Q. In some embodiments, the first electrode 311 and the second electrode 312 may be disposed at two vertices facing each other among the vertices of the virtual quadrilateral Q. The two of the third electrodes 313 may be disposed at two vertices facing each other among the vertices of the virtual quadrilateral Q. The virtual quadrilateral Q may be a rectangle, rhombus, square, etc.

It can be understood that one of the first electrodes 311, one of the second electrodes 312, and two of the third electrodes 313 are respectively disposed at the four vertices of the virtual quadrilateral Q, and the light-emitting units 70 of corresponding colors are also disposed at the four vertices of the virtual quadrilateral Q, thereby forming the arrangement structure of sub-pixels in the display panel. Through this sub-pixel arrangement structure, color rendering driving can be performed by sharing adjacent sub-pixels, allowing high resolution to be achieved with a small number of pixels.

In some embodiments, as shown in FIG. 3, in a region corresponding to the virtual quadrilateral Q, the two of the third electrodes 313 are spaced apart along a first direction X, the first electrode 311 and the second electrode 312 are spaced apart along a second direction Y, and the first direction X, the second direction Y, and a thickness direction Z of the array substrate 100 intersect pairwise. Optionally, the first direction X, the second direction Y, and the thickness direction Z of the array substrate 100 are perpendicular to each other.

Within one virtual quadrilateral Q, that is, for one virtual quadrilateral Q, the two of the third electrodes 313 are spaced apart along the first direction X, the first electrode 311 and the second electrode 312 are spaced apart along the second direction Y, and at least a portion of the orthographic projection of the first electrode 311 on a first plane and at least a portion of the orthographic projection of the second electrode 312 on the first plane are both located between the orthographic projections of the two of the third electrodes 313 on the first plane. The first plane is a plane perpendicular to the second direction Y. Optionally, the centroid of the first electrode 311 passes through a perpendicular line to the midpoint of the line connecting the centroids of the two third electrodes 313. The centroid of the second electrode 312 passes through a perpendicular line to the midpoint of the line connecting the centroids of the two third electrodes 313. Optionally, the line connecting the centroid of the first electrode 311 and the centroid of the second electrode 312 may be parallel to the second direction Y or may intersect the second direction Y.

In some optional embodiments, as shown in FIG. 2 to FIG. 4, the constant signal lines 22 include a first constant signal line 221 and a second constant signal line 222. The non-constant signal lines 21 include a first non-constant signal line 211. The first constant signal line 221, the second constant signal line 222, and the first non-constant signal line 211 all extend along the first direction X and are spaced apart along the second direction Y. An orthographic projection of at least one of the first constant signal line 221 and the second constant signal line 222 on the base 10 at least overlaps with an orthographic projection of the first electrode 311 on the base 10. An orthographic projection of at least one of the first constant signal line 221 and the second constant signal line 222 on the base 10 at least overlaps with an orthographic projection of the second electrode 312 on the base 10. And an orthographic projection of the first non-constant signal line 211 on the base 10 at least overlaps with the orthographic projection of the first electrode 311 on the base 10 and the orthographic projection of the second electrode 312 on the base 10.

Optionally, the functions of the first constant signal line 221 and the second constant signal line 222 are different.

Optionally, the number of first constant signal lines 221 may include one or more.

Optionally, the number of second constant signal lines 222 may include one or more.

Optionally, the number of first non-constant signal lines 211 may include one or more.

Optionally, the constant signal line 22 may further include a third constant signal line, a fourth constant signal line, or more.

Optionally, the non-constant signal line 21 may further include a second non-constant signal line, a third non-constant signal line, a fourth non-constant signal line, or more.

The embodiment of the present application does not limit the arrangement of the first constant signal line 221, the second constant signal line 222, and the third constant signal line 22. For example, the first constant signal line 221, the second constant signal line 222, and the third constant signal line 22 may be alternately arranged along the second direction Y, or may be arranged according to a predetermined arrangement pattern based on actual design requirements.

In some embodiments, the orthographic projection of the first constant signal line 221 on the base 10 and the orthographic projection of the first non-constant signal line 211 on the base 10 overlap with the orthographic projection of the first electrode 311 on the base 10. Moreover, the orthographic projection of the first constant signal line 221 on the base 10 and the orthographic projection of the first non-constant signal line 211 on the base 10 overlap with the orthographic projection of the second electrode 312 on the base 10. In other embodiments, the orthographic projection of the second constant signal line 222 on the base 10 and the orthographic projection of the first non-constant signal line 211 on the base 10 overlap with the orthographic projection of the first electrode 311 on the base 10. Moreover, the orthographic projection of the second constant signal line 222 on the base 10 and the orthographic projection of the first non-constant signal line 211 on the base 10 overlap with the orthographic projection of the second electrode 312 on the base 10. In still other embodiments, the orthographic projection of the first constant signal line 221 on the base 10, the orthographic projection of the second constant signal line 222 on the base 10, and the orthographic projection of the first non-constant signal line 211 on the base 10 overlap with the orthographic projection of the first electrode 311 on the base 10. Moreover, the orthographic projection of the first constant signal line 221 on the base 10, the orthographic projection of the second constant signal line 222 on the base 10, and the orthographic projection of the first non-constant signal line 211 on the base 10 overlap with the orthographic projection of the second electrode 312 on the base 10. In other embodiments, the orthographic projection of at least one of the first constant signal line 221 and the second constant signal line 222 on the base 10 and the orthographic projection of the first non-constant signal line 211 on the base 10 may also at least partially overlap with the orthographic projection of the third electrode 313 on the base 10.

By the above arrangement, the embodiment of the present application is conducive to reducing the possibility of crosstalk between the non-constant signal line 21 and the pixel electrode 31, while increasing the flexibility of arranging the constant signal line 22 and the non-constant signal line 21, and improving the application range of the array substrate 100.

In some optional embodiments, the orthographic projection of the first constant signal line 221 on the base 10 and the orthographic projection of the second constant signal line 222 on the base 10 both overlap with the orthographic projection of the first electrode 311 on the base 10. Moreover, the orthographic projection of the first constant signal line 221 on the base 10 and the orthographic projection of the second constant signal line 222 on the base 10 both overlap with the orthographic projection of the second electrode 312 on the base 10.

In some optional embodiments, the second constant signal line 222 corresponding to the first electrode 311 or the second electrode 312 is disposed on both sides of the second constant signal line 222 corresponding to the same first electrode 311 or the same second electrode 312 along a width direction of the second constant signal line 222; and/or, the second constant signal line 222 corresponding to the first electrode 311 or the second electrode 312 is disposed on both sides of the second constant signal line 222 corresponding to the same first electrode 311 or the same second electrode 312 along the width direction of the second constant signal line 222.

The “corresponding” in the second constant signal line 222 corresponding to the first electrode 311 refers to the second constant signal line 222 configured to drive the first electrode 311, and the portion of the orthographic projection of this second constant signal line 222 on the base 10 that overlaps with the orthographic projection of this first electrode 311 on the base 10. Similarly, the “corresponding” in the first constant signal line 221 corresponding to the first electrode 311, the first non-constant signal line 211 corresponding to the first electrode 311, the first constant signal line 221 corresponding to the second electrode 312, the second constant signal line 222 corresponding to the second electrode 312, the first non-constant signal line 211 corresponding to the second electrode 312, the first constant signal line 221 corresponding to the third electrode 313, the second constant signal line 222 corresponding to the third electrode 313, and the first non-constant signal line 211 corresponding to the third electrode 313 is the same as the “corresponding” in the second constant signal line 222 corresponding to the first electrode 311, and will not be repeated.

In some embodiments, as shown in FIG. 4, the second constant signal line 222 corresponding to the first electrode 311 or the second electrode 312 is disposed on both sides along its own width direction with the first constant signal line 221 corresponding to the same first electrode 311 or the same second electrode 312. Moreover, the second constant signal line 222 corresponding to the first electrode 311 or the second electrode 312 is disposed on both sides along its own width direction with the first non-constant signal line 211 corresponding to the same first electrode 311 or the same second electrode 312. Optionally, two first non-constant signal lines 211 and two first constant signal lines 221 may be arranged symmetrically with respect to the second constant signal line 222. For example, the arrangement of the two first non-constant signal lines 211, the two first constant signal lines 221, and the second constant signal line 222 along the second direction Y may be, in order: first constant signal line 221, first non-constant signal line 211, second constant signal line 222, first non-constant signal line 211, first constant signal line 221; or it may be: first non-constant signal line 211, first constant signal line 221, second constant signal line 222, first constant signal line 221, first non-constant signal line 211. It is obvious that the two first non-constant signal lines 211 and the two first constant signal lines 221 may also be arranged asymmetrically with respect to the second constant signal line 222. For example: first constant signal line 221, first non-constant signal line 211, second constant signal line 222, first constant signal line 221, first non-constant signal line 211.

In other embodiments, the second constant signal line 222 corresponding to the first electrode 311 or the second electrode 312 is disposed on both sides along its own width direction with the first constant signal line 221 corresponding to the same first electrode 311 or the same second electrode 312. In still other embodiments, the second constant signal line 222 corresponding to the first electrode 311 or the second electrode 312 is disposed on both sides along its own width direction with the first non-constant signal line 211 corresponding to the same first electrode 311 or the same second electrode 312.

The width direction of the second constant signal line 222 may be a direction perpendicular to the extending direction of the second constant signal line 222.

In these optional embodiments, by arranging the first constant signal line 221 on both sides of the second constant signal line 222 along its width direction, it is conducive to increasing the overlapping area between the constant signal line 22 and the pixel electrode 31, thereby reducing the possibility of crosstalk between the non-constant signal line 21 and the pixel electrode 31. By arranging the first non-constant signal line 211 on both sides of the second constant signal line 222 along its width direction, it is conducive to improving the design flexibility of the first non-constant signal line 211 and increasing the application range of the array substrate 100.

In some embodiments, a plurality of first constant signal lines 221 and/or a plurality of first non-constant signal lines 211 disposed on both sides of the second constant signal line 222 corresponding to the first electrode 311 or the second electrode 312 along its width direction have orthographic projections on the base 10 that are symmetrically arranged about a center line of the orthographic projection of the first electrode 311 on the base 10 along the first direction X.

For example, the number of first constant signal lines 221 is two, and the number of first non-constant signal lines 211 is two. The orthographic projections of the two first constant signal lines 221 on the base 10 are symmetrically arranged about the center line of the orthographic projection of the first electrode 311 on the base 10 along the first direction X. The orthographic projections of the two first non-constant signal lines 211 on the base 10 are symmetrically arranged about the center line of the orthographic projection of the first electrode 311 on the base 10 along the first direction X. Alternatively, the orthographic projection of one first constant signal line 221 on the base 10 and the orthographic projection of one first non-constant signal line 211 on the base 10 are symmetrically arranged about the center line of the orthographic projection of the first electrode 311 on the base 10 along the first direction X.

In some embodiments, the first non-constant signal line 211 corresponding to the first electrode 311 or the second electrode 312 includes a connected first segment 211a and a second segment 211b. The orthographic projection of the first segment 211a on the base 10 intersects a center line of the orthographic projection of the first electrode 311 or the second electrode 312 on the base 10 along the second direction Y. A minimum distance between an orthographic projection of the second segment 211b on the base 10 and an orthographic projection of the second constant signal line 222 adjacent to the second segment 211b on the base 10 is greater than a maximum distance between the orthographic projection of the first segment 211a on the base 10 and an orthographic projection of the second constant signal line 222 adjacent to the first segment 211a on the base 10.

It can be understood that the orthographic projections of the first segment 211a and the second segment 211b on the base 10 are both located within the orthographic projection of the first electrode 311 or the second electrode 312 on the base 10.

For example, the first non-constant signal line 211 corresponding to the first electrode 311 includes a connected first segment 211a and a second segment 211b. The orthographic projection of the first segment 211a on the base 10 intersects the center line of the orthographic projection of the first electrode 311 on the base 10 along the second direction Y. The minimum distance between the orthographic projection of the second segment 211b on the base 10 and the orthographic projection of the second constant signal line 222 adjacent to the second segment 211b on the base 10 is greater than the maximum distance between the orthographic projection of the first segment 211a on the base 10 and the orthographic projection of the second constant signal line 222 adjacent to the first segment 211a on the base 10. Or, the first non-constant signal line 211 corresponding to the second electrode 312 includes a connected first segment 211a and a second segment 211b. The orthographic projection of the first segment 211a on the base 10 intersects the center line of the orthographic projection of the second electrode 312 on the base 10 along the second direction Y. The minimum distance between the orthographic projection of the second segment 211b on the base 10 and the orthographic projection of the second constant signal line 222 adjacent to the second segment 211b on the base 10 is greater than the maximum distance between the orthographic projection of the first segment 211a on the base 10 and the orthographic projection of the second constant signal line 222 adjacent to the first segment 211a on the base 10. Optionally, under the condition that the orthographic projection of the second segment 211b on the base 10 and the orthographic projection of the adjacent second constant signal line 222 on the base 10 are designed with equal spacing, the minimum distance between the orthographic projection of the second segment 211b on the base 10 and the orthographic projection of the adjacent second constant signal line 222 on the base 10 is the distance between the orthographic projection of the second segment 211b on the base 10 and the orthographic projection of the adjacent second constant signal line 222 on the base 10. The second segment 211b and the adjacent second constant signal line 222 can also be designed with unequal spacing.

Optionally, the orthographic projection of the first segment 211a on the base 10 is parallel to the orthographic projection of the second constant signal line 222 on the base 10.

Optionally, the orthographic projection of the second segment 211b on the base 10 is parallel to the orthographic projection of the second constant signal line 222 on the base 10.

In some embodiments, an extension direction of the orthographic projection of the second segment 211b on the base 10 intersects an extension direction of the orthographic projection of the second constant signal line 222 on the base 10. And along a direction away from the centroid of the first electrode 311 or the second electrode 312, a distance between the orthographic projection of the second segment 211b on the base 10 and the orthographic projection of the adjacent second constant signal line 222 on the base 10 gradually increases.

Optionally, the orthographic projection of the second segment 211b on the base 10 may be a straight line inclined relative to the extension direction of the orthographic projection of the second constant signal line 222 on the base 10. The second segment 211b may also include a plurality of sub-segments. Along the direction away from the centroid of the first electrode 311 or the second electrode 312, the distance between the orthographic projections of the plurality of sub-segments on the base 10 and the orthographic projection of the adjacent constant signal line 22 on the base 10 gradually increases.

In some optional embodiments, the first non-constant signal line 211 corresponding to the first electrode 311 or the second electrode 312 further includes a third segment 211c. The third segment 211c is connected to an end of the first segment 211a away from the second segment 211b. A minimum distance between an orthographic projection of the third segment 211c on the base 10 and an orthographic projection of the second constant signal line 222 adjacent to the third segment 211c on the base 10 is greater than a maximum distance between the orthographic projection of the first segment 211a on the base 10 and the orthographic projection of the second constant signal line 222 adjacent to the first segment 211a on the base 10.

For example, the first non-constant signal line 211 corresponding to the first electrode 311 further includes a third segment 211c. The third segment 211c is connected to the end of the first segment 211a away from the second segment 211b. The minimum distance between the orthographic projection of the third segment 211c on the base 10 and the orthographic projection of the second constant signal line 222 adjacent to the third segment 211c on the base 10 is greater than the maximum distance between the orthographic projection of the first segment 211a on the base 10 and the orthographic projection of the second constant signal line 222 adjacent to the first segment 211a on the base 10. And/or, the first non-constant signal line 211 corresponding to the second electrode 312 further includes a third segment 211c. The third segment 211c is connected to the end of the first segment 211a away from the second segment 211b. The minimum distance between the orthographic projection of the third segment 211c on the base 10 and the orthographic projection of the second constant signal line 222 adjacent to the third segment 211c on the base 10 is greater than the maximum distance between the orthographic projection of the first segment 211a on the base 10 and the orthographic projection of the second constant signal line 222 adjacent to the first segment 211a on the base 10.

In some optional embodiments, the orthographic projection of the third segment 211c on the base 10 is parallel to the orthographic projection of the second constant signal line 222 on the base 10.

In some optional embodiments, a distance between the orthographic projection of the third segment 211c on the base 10 and the orthographic projection of the adjacent second constant signal line 222 on the base 10 gradually increases along a direction away from the centroid of the orthographic projection of the first electrode 311 or the second electrode 312 on the base 10.

For example, in a direction from the centroid of the first electrode 311 toward an edge of the first electrode 311 along the first direction X, the distance between the third segment 211c and the adjacent second constant signal line 222 gradually increases. And/or, in a direction from the centroid of the second electrode 312 toward an edge of the second electrode 312 along the first direction X, the distance between the third segment 211c and the adjacent second constant signal line 222 gradually increases. The “gradually increases” here may be a stepwise increase or a proportional increase. Through the above arrangement, a light-transmitting region can be formed between the second constant signal line 222 and the first non-constant signal line 211 to increase the light transmittance of the display panel 200.

In some embodiments, along the second direction Y, a distance between the orthographic projection of the second constant signal line 222 corresponding to the first electrode 311 or the second electrode 312 on the base 10 and the orthographic projection of the adjacent first non-constant signal line 211 on the base 10 is equal to a distance between the orthographic projection of the first non-constant signal line 211 corresponding to the first electrode 311 or the second electrode 312 on the base 10 and the orthographic projection of the adjacent first constant signal line 221 on the base 10.

For example, along the second direction Y, the distance between the orthographic projection of the second constant signal line 222 corresponding to the first electrode 311 on the base 10 and the orthographic projection of the adjacent first non-constant signal line 211 on the base 10 is equal to the distance between the orthographic projection of the first non-constant signal line 211 corresponding to the first electrode 311 on the base 10 and the orthographic projection of the adjacent first constant signal line 221 on the base 10. And/or, along the second direction Y, the distance between the orthographic projection of the second constant signal line 222 corresponding to the second electrode 312 on the base 10 and the orthographic projection of the adjacent first non-constant signal line 211 on the base 10 is equal to the distance between the orthographic projection of the first non-constant signal line 211 corresponding to the second electrode 312 on the base 10 and the orthographic projection of the adjacent first constant signal line 221 on the base 10. Through the above arrangement, it is conducive to increasing the flatness of the first electrode 311 and the second electrode 312, and reducing the possibility of color shift of the light-emitting units 70 corresponding to the first electrode 311 and the second electrode 312 at different viewing angles.

In some embodiments, the first constant signal line 221 includes a power line. For example, the power line may include a first power line for transmitting a power supply voltage to an anode and a second power line for transmitting a power supply voltage to a cathode. The first constant signal line 221 is at least one of the first power line and the second power line.

In some embodiments, the second constant signal line 222 includes an initialization voltage line. For example, the initialization voltage line may include a first initialization voltage line for resetting a gate of a thin film transistor 40 and a second initialization voltage line for resetting an anode. The second constant signal line 222 is at least one of the first initialization voltage line and the second initialization voltage line.

In some embodiments, the first non-constant signal line 211 includes a data line.

In some optional embodiments, as shown in FIG. 1 and FIG. 2, in a region corresponding to the virtual quadrilateral Q, the first constant signal line 221 is provided with a via K1. The orthographic projection of the pixel electrode 31 on the base 10 at least partially overlaps with an orthographic projection of a pattern surrounded and defined by a contour of the via K1 on the base 10.

Optionally, the first constant signal line 221 is provided with a closed via K1 structure. Optionally, the shape of the via K1 may be circular, elliptical, rectangular, or other shapes.

Optionally, within one virtual quadrilateral Q, the number of vias K1 may be one or more.

It can be understood that within one virtual quadrilateral Q, portions of the first electrode 311, the second electrode 312, and the third electrode 313 extend toward the center of the virtual quadrilateral Q to occupy a portion of the area within the virtual quadrilateral Q. The orthographic projection of the first electrode 311 on the base 10 may at least partially overlap with the orthographic projection of the pattern surrounded and defined by the contour of the via K1 on the base 10. And/or, the orthographic projection of the second electrode 312 on the base 10 may at least partially overlap with the orthographic projection of the pattern surrounded and defined by the contour of the via K1 on the base 10. And/or, the orthographic projection of the third electrode 313 on the base 10 may at least partially overlap with the orthographic projection of the pattern surrounded and defined by the contour of the via K1 on the base 10. Taking the first electrode 311 as an example, “at least partially overlapping” here means that a portion of the orthographic projection of the first electrode 311 on the base 10 overlaps with a portion of the orthographic projection of the pattern surrounded and defined by the contour of the via K1 on the base 10, or it may mean that the orthographic projection of the pattern surrounded and defined by the contour of the via K1 on the base 10 falls within the orthographic projection of the first electrode 311 on the base 10.

The contour of the via K1 refers to the edge of the via K1 structure on the first constant signal line 221.

Optionally, the via K1 may be located at the centroid of the virtual quadrilateral Q or at any position of the virtual quadrilateral Q.

In these optional embodiments, through the above arrangement, it is conducive to increasing the overlapping area between the pixel electrode 31 and the first constant signal line 221, thereby enhancing the capacitive coupling effect between the pixel electrode 31 and the constant signal line 22, reducing the possibility of crosstalk between the pixel electrode 31 and the non-constant signal line 21, improving the reliability of the array substrate 100, and thereby improving the reliability of the display panel.

In some optional embodiments, as shown in FIG. 1 to FIG. 4, in a region corresponding to the virtual quadrilateral Q, the first constant signal line 221 includes a surface signal portion 221a and a connection portion 221b connected to each other. A dimension of the surface signal portion 221a along the second direction Y is greater than a dimension of the connection portion 221b along the second direction Y. The surface signal portion 221a and the connection portion 221b surround and define the via K1. The orthographic projection of the third electrode 313 on the base 10 at least partially overlaps with an orthographic projection of the surface signal portion 221a on the base 10.

Optionally, an orthographic projection of an edge of the surface signal portion 221a on the base 10 is at least partially located within the orthographic projection of the third electrode 313 on the base 10.

Optionally, the edge of the surface signal portion 221a includes a first edge L1 extending along the first direction X. At least a portion of an orthographic projection of the first edge L1 on the base 10 is located within the orthographic projection of the third electrode 313 on the base 10.

Optionally, the orthographic projection of the first edge L1 on the base 10 is entirely located within the orthographic projection of the third electrode 313 on the base 10.

Optionally, the first edge L1 is a straight edge.

Optionally, in a region corresponding to one virtual quadrilateral Q, the number of surface signal portions 221a may include one or more. Under the condition that only one surface signal portion 221a is provided in a region corresponding to one virtual quadrilateral Q, the surface signal portions 221a in adjacent regions corresponding to the virtual quadrilateral Q are connected by connection portions 221b. Under the condition that multiple surface signal portions 221a are provided in a region corresponding to one virtual quadrilateral Q, the multiple surface signal portions 221a in one region corresponding to the virtual quadrilateral Q are connected by connection portions 221b, and the surface signal portions 221a in adjacent regions corresponding to the virtual quadrilateral Q are connected by connection portions 221b. “In a region corresponding to the virtual quadrilateral” here refers to a region including one virtual quadrilateral and the surface signal portions, connection portions, and other structures corresponding to this virtual quadrilateral.

The surface signal portion 221a and the connection portion 221b surround and define the via K1. A portion of the edge of the surface signal portion 221a and a portion of the edge of the connection portion 221b form the contour of the via K1.

Optionally, a portion of the orthographic projection of the third electrode 313 on the base 10 overlaps with a portion of the orthographic projection of the surface signal portion 221a on the base 10; or the orthographic projection of the third electrode 313 on the base 10 falls within the orthographic projection of the surface signal portion 221a on the base 10; or the orthographic projection of the surface signal portion 221a on the base 10 falls within the orthographic projection of the third electrode 313 on the base 10.

In some embodiments, in the region corresponding to the virtual quadrilateral Q, the two third electrodes 313 are spaced apart along the first direction X. By making the dimension of the surface signal portion 221a along the second direction Y greater than the dimension of the connection portion 221b along the second direction Y, the overlapping area between the surface signal portion 221a and the third electrode 313 on the base 10 is increased. At the same time, the dimension of the third electrode 313 along the first direction X is reduced, making the distance between the two third electrodes 313 along the first direction X smaller, thereby reducing the overall area of the virtual quadrilateral Q, and further reducing the area of the sub-pixels in the display panel, improving the resolution of the display panel.

As shown in FIG. 4, in the region corresponding to the virtual quadrilateral Q, the surface signal portions 221a include two surface signal portions. The two surface signal portions 221a are disposed on two sides of the via K1 along the first direction X, and the two surface signal portions 221a are disposed in one-to-one correspondence with the two third electrodes 313.

Optionally, the two surface signal portions 221a may be connected by one or more connection portions 221b.

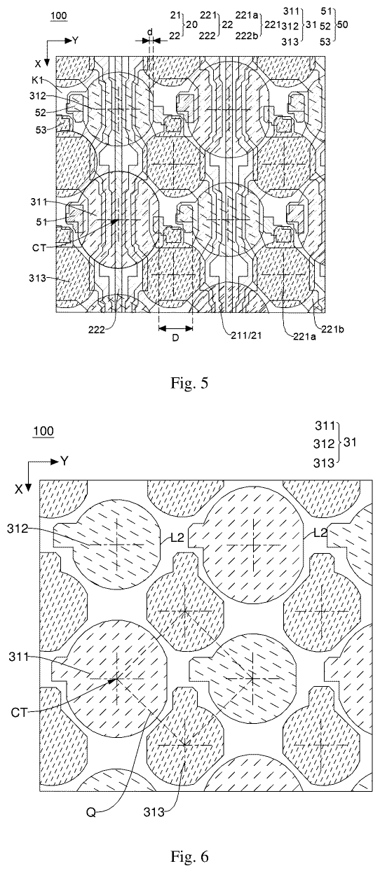

FIG. 5 is a partially enlarged schematic structural view of another array substrate 100 according to an embodiment of the present application.

In some optional embodiments, as shown in FIG. 2 and FIG. 5, in a region corresponding to the virtual quadrilateral Q, an orthographic projection of at least one of the first electrode 311 and the second electrode 312 on the base 10 overlaps with an orthographic projection of the connection portion 221b on the base 10.

In some embodiments, in the region corresponding to the virtual quadrilateral Q, the orthographic projection of the first electrode 311 on the base 10 overlaps with the orthographic projection of the connection portion 221b on the base 10, and the orthographic projection of the second electrode 312 on the base 10 overlaps with the orthographic projection of the connection portion 221b on the base 10. In other embodiments, in the region corresponding to the virtual quadrilateral Q, the orthographic projection of the first electrode 311 on the base 10 overlaps with the orthographic projection of the connection portion 221b on the base 10. In still other embodiments, in the region corresponding to the virtual quadrilateral Q, the orthographic projection of the second electrode 312 on the base 10 overlaps with the orthographic projection of the connection portion 221b on the base 10.

It can be understood that under the condition that the orthographic projections of both the first electrode 311 and the second electrode 312 on the base 10 overlap with the orthographic projection of the connection portion 221b on the base 10, the orthographic projection of the first electrode 311 on the base 10 and the orthographic projection of the second electrode 312 on the base 10 overlap with the orthographic projections of different connection portions 221b on the base 10, respectively.

By the above arrangement, the embodiment of the present application is conducive to increasing the overlapping area between the first electrode 311 and/or the second electrode 312 and the constant signal line 22, thereby reducing the possibility of crosstalk between the first electrode 311 and/or the second electrode 312 and the non-constant signal line 21, and further reducing the possibility of display abnormalities of the light-emitting units 70 corresponding to the first electrode 311 and/or the second electrode 312, improving the reliability of the display panel.

In the region corresponding to the virtual quadrilateral Q, the connection portions 221b include two connection portions. The two connection portions 221b are disposed on two sides of the via K1 along the second direction Y. An orthographic projection of one of the two connection portions 221b on the base 10 at least partially overlaps with the orthographic projection of the first electrode 311 on the base 10. An orthographic projection of the other of the two connection portions 221b on the base 10 at least partially overlaps with the orthographic projection of the second electrode 312 on the base 10.

Optionally, the two connection portions 221b may both be electrically connected to the surface signal portions 221a located on both sides of the via K1 along the first direction X. Alternatively, only one connection portion 221b may electrically connect the surface signal portions 221a located on both sides of the via K1 along the first direction X. The other connection portion 221b may only be electrically connected to one of the two surface signal portions 221a located on both sides of the via K1 along the first direction X, or the other connection portion 221b may not be electrically connected to the surface signal portion 221a. It is obvious that the two connection portions 221b may both not be electrically connected to the surface signal portion 221a.

In these optional embodiments, through the above arrangement, it is conducive to further increasing the overlapping area between all pixel electrodes 31 and the constant signal line 22, to reduce the possibility of crosstalk between all pixel electrodes 31 and the non-constant signal line 21, and improve the overall display effect of the display panel.

In some optional embodiments, as shown in FIG. 2 to FIG. 5, in a region corresponding to the virtual quadrilateral Q, along the second direction Y, an orthographic projection of at least one of the first electrode 311 and the second electrode 312 on the base 10 overlaps with the orthographic projection of the pattern surrounded and defined by the contour of the via K1 on the base 10.

Optionally, the connection portion 221b may include a first connection portion 221b1 and a second connection portion 221b2. The orthographic projection of the first electrode 311 on the base 10 at least partially overlaps with an orthographic projection of the first connection portion 221b1 on the base 10. The orthographic projection of the second electrode 312 on the base 10 at least partially overlaps with an orthographic projection of the second connection portion 221b2 on the base 10.

In some embodiments, in the region corresponding to the virtual quadrilateral Q, a portion of the first electrode 311 extends along the second direction Y and toward the centroid of the via K1, so that the first electrode 311 includes a first region, a second region, and a third region. The orthographic projection of the first region on the base 10 is located on a side of the orthographic projection of the first connection portion 221b1 on the base 10 away from the contour of the via K1. The orthographic projection of the second region on the base 10 overlaps with the orthographic projection of the first connection portion 221b1 on the base 10. The orthographic projection of the third region on the base 10 overlaps with the orthographic projection of the pattern surrounded and defined by the contour of the via K1 on the base 10, and a portion of the orthographic projection of the third region on the base 10 is located within the orthographic projection of the pattern surrounded and defined by the contour of the via K1 on the base 10. The overlapping relationship between the second electrode 312 and the pattern surrounded and defined by the contour of the via K1 is the same as that of the first electrode 311 and the pattern surrounded and defined by the contour of the via K1, and will not be repeated in this embodiment of the present application.

In some embodiments, in the region corresponding to the virtual quadrilateral Q, along the second direction Y, the orthographic projections of both the first electrode 311 and the second electrode 312 on the base 10 extend beyond the orthographic projection of the connection portion 221b that overlaps with them on the base 10 and overlap with the orthographic projection of the pattern surrounded and defined by the contour of the via K1 on the base 10. In other embodiments, in the region corresponding to the virtual quadrilateral Q, along the second direction Y, the orthographic projection of the first electrode 311 on the base 10 extends beyond the orthographic projection of the first connection portion 221b1 on the base 10 and overlaps with the orthographic projection of the pattern surrounded and defined by the contour of the via K1 on the base 10. In still other embodiments, in the region corresponding to the virtual quadrilateral Q, along the second direction Y, the orthographic projection of the second electrode 312 on the base 10 extends beyond the orthographic projection of the second connection portion 221b2 on the base 10 and overlaps with the orthographic projection of the pattern surrounded and defined by the contour of the via K1 on the base 10.

By the above arrangement, the embodiment of the present application is conducive to increasing the overlapping area between the first electrode 311 and/or the second electrode 312 and the connection portion 221b, thereby increasing the overlapping area between the first electrode 311 and/or the second electrode 312 and the constant signal line 22, enhancing the capacitive coupling effect between the first electrode 311 and/or the second electrode 312 and the constant signal line 22, reducing the possibility of crosstalk between the pixel electrode 31 and the non-constant signal line 21, and improving the reliability of the display panel.

FIG. 6 is a partially enlarged schematic structural view of a first electrode layer in another array substrate 100 according to an embodiment of the present application.

In some embodiments, as shown in FIG. 5 and FIG. 6, an edge of at least one of the first electrode 311 and the second electrode 312 includes a second edge L2. At least a portion of an orthographic projection of the second edge L2 on the base 10 is located within the orthographic projection of the pattern surrounded and defined by the contour of the via K1 on the base 10. In some embodiments, the second edge L2 extends along the first direction X.

Under the condition that, in the region corresponding to the virtual quadrilateral Q, along the second direction Y, the orthographic projection of the first electrode 311 on the base 10 extends beyond the orthographic projection of the first connection portion 221b1 on the base 10 and overlaps with the orthographic projection of the pattern surrounded and defined by the contour of the via K1 on the base 10, at least a portion of the orthographic projection of the second edge L2 on the base 10 is located within the orthographic projection of the pattern surrounded and defined by the contour of the via K1 on the base 10. The overlapping relationship between the second edge L2 included in the edge of the second electrode 312 along the second direction Y and the pattern surrounded and defined by the contour of the via K1 is the same as that of the second edge L2 included in the edge of the first electrode 311 along the second direction Y and the pattern surrounded and defined by the contour of the via K1, or it may be different.

Optionally, the orthographic projection of the second edge L2 on the base 10 is entirely located within the orthographic projection of the pattern surrounded and defined by the contour of the via K1 on the base 10.

In some embodiments, the edges of both the first electrode 311 and the second electrode 312 include the second edge L2. The second edge L2 extends along the first direction X, that is, the edges of both the first electrode 311 and the second electrode 312 along the second direction Y are the second edge L2. At least a portion of the orthographic projection of the second edge L2 on the base 10 is located within the orthographic projection of the pattern surrounded and defined by the contour of the via K1 on the base 10. In other embodiments, the edge of the first electrode 311 along the second direction Y is the second edge L2. At least a portion of the orthographic projection of the second edge L2 on the base 10 is located within the orthographic projection of the pattern surrounded and defined by the contour of the via K1 on the base 10. In still other embodiments, the edge of the second electrode 312 along the second direction Y is the second edge L2. At least a portion of the orthographic projection of the second edge L2 on the base 10 is located within the orthographic projection of the pattern surrounded and defined by the contour of the via K1 on the base 10.

In these optional embodiments, by setting the second edge L2, the [symbol] region of the first electrode 311 and the second electrode 312 on the via K1 in the thickness direction Z is reduced, so that the via can serve as a light-transmitting hole or an avoidance hole for other conductive structures, thereby increasing the overlapping area between the first electrode 311 and the second electrode 312 and the constant signal line 22 while improving the design flexibility of the via K1.

In other embodiments, the edge of the third electrode 313 includes the second edge L2. The second edge L2 extends along the first direction X, that is, the edge of the third electrode 313 along the second direction Y is the second edge L2, thereby reducing the dimension of the third electrode 313 along the second direction Y.

Optionally, the second edge is a straight edge.

In some optional embodiments, as shown in FIG. 1 to FIG. 4, the array substrate 100 further includes a thin film transistor 40. The pixel electrode 31 is electrically connected to the thin film transistor through an electrode connection portion 50. A plurality of electrode connection portions 50 are provided. Orthographic projections of at least a portion of the plurality of electrode connection portions 50 on the base 10 are located within the orthographic projection of the pattern surrounded and defined by the contour of the via K1 on the base 10.

Optionally, the thin film transistor 40 includes a source, a drain, a gate, and a semiconductor. The source and the drain are spaced apart and both are electrically connected to the semiconductor. Optionally, the source and the drain may be located on the same side, the semiconductor is located between the source/drain layer and the base 10, the gate may be located between the semiconductor and the source/drain layer, or the gate may be located between the semiconductor and the base 10.

The pixel electrode 31 and the thin film transistor 40 are electrically connected through the electrode connection portion 50, so that the thin film transistor 40 can control and drive the pixel electrode 31. Optionally, the pixel electrode may be electrically connected to the source through the electrode connection portion 50, or the pixel electrode 31 may be electrically connected to the drain through the electrode connection portion 50.

Optionally, the constant signal line 22 may be located between the source/drain layer and the first electrode layer 30.

Optionally, the non-constant signal line 21 may be located between the source/drain layer and the first electrode layer 30.

Optionally, the orthographic projections of the plurality of electrode connection portions 50 on the base 10 are all located within the orthographic projection of the pattern surrounded and defined by the contour of the via K1 on the base 10.

Optionally, the electrode connection portions 50 include a plurality of electrode connection portions. The orthographic projections of a portion of the plurality of electrode connection portions 50 on the base 10 are all located within the orthographic projection of the pattern surrounded and defined by the contour of the via K1 on the base 10.

Under the condition that the constant signal line 22 is located between the source/drain layer and the first electrode layer 30, the via K1 can serve as an avoidance hole, allowing the electrode connection portion 50 to pass through the via K1 to electrically connect the thin film transistor 40 and the pixel electrode 31, thereby increasing the area of the constant signal line 22 while reducing the possibility of interference between the electrode connection portion 50 and the constant signal line 22, and improving the manufacturing yield of the array substrate 100.

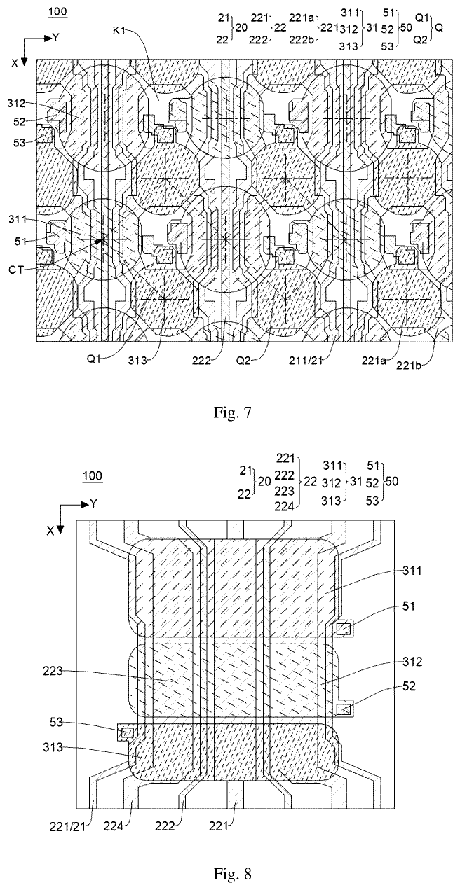

FIG. 7 is a partially enlarged schematic structural view of another array substrate 100 according to an embodiment of the present application.

In some optional embodiments, as shown in FIG. 1 and FIG. 7, the electrode connection portions 50 include a first electrode connection portion 51 and a second electrode connection portion 52. The first electrode 311 is electrically connected to the thin film transistor 40 through the first electrode connection portion 51. The second electrode 312 is electrically connected to the thin film transistor 40 through the second electrode connection portion 52. An orthographic projection of one of the first electrode connection portion 51 corresponding to the first electrode 311 and the second electrode connection portion 52 corresponding to the second electrode 312 adjacent to the first electrode 311 on the base 10 is located within the orthographic projection of the pattern surrounded and defined by the contour of the via K1 within the virtual quadrilateral Q on the base 10. An orthographic projection of the other on the base 10 is located within an orthographic projection of a pattern surrounded and defined by the contour of a via K1 within another virtual quadrilateral adjacent to the virtual quadrilateral Q on the base 10.

For example, two adjacent virtual quadrilaterals Q along the second direction Y are a first virtual quadrilateral Q1 and a second virtual quadrilateral Q2, respectively. The first virtual quadrilateral Q1 and the second virtual quadrilateral Q2 share one first electrode 311. In the second virtual quadrilateral Q2, the orthographic projection of the first electrode connection portion 51 corresponding to the first electrode 311 on the base 10 is located within the orthographic projection of the pattern surrounded and defined by the contour of the via K1 within the first virtual quadrilateral Q1 on the base 10. The orthographic projection of the second electrode connection portion 52 corresponding to the second electrode 312 on the base 10 is located within the orthographic projection of the pattern surrounded and defined by the contour of the via K1 within the second virtual quadrilateral Q2 on the base 10.

It can be understood that the first electrode 311 and the second electrode 312 are connected to different thin film transistors 40, that is, the first electrode connection portion 51 and the second electrode connection portion 52 are electrically connected to different thin film transistors 40. By arranging the electrode connection portions 50 corresponding to the first electrode 311 and the second electrode 312 in one virtual quadrilateral Q to pass through different vias K1, it is conducive to reducing the number of electrode connection portions 50 arranged in one via, thereby reducing the area of the via K1, so as to reduce the spacing between the first electrode 311, the second electrode 312, and the third electrode 313, and thus reducing the area of the corresponding sub-pixels, improving the resolution of the display panel.

In some embodiments, the electrode connection portion 50 further includes a third electrode connection portion 53. The third electrode 313 is connected to the thin film transistor 40 through the third electrode connection portion 53. In the region corresponding to the virtual quadrilateral Q, the third electrodes 313 include two third electrodes, and the third electrode connection portions 53 also include two third electrode connection portions. The orthographic projections of the two third electrode connection portions 53 on the base 10 may be located within the orthographic projection of the pattern surrounded and defined by the contour of the via K1 within the same virtual quadrilateral Q on the base 10. Alternatively, the two third electrode connection portions 53 may be arranged such that the orthographic projection of one of the third electrode connection portions 53 on the base 10 is located within the orthographic projection of the pattern surrounded and defined by the contour of the via K1 within the virtual quadrilateral Q on the base 10, and the orthographic projection of the other on the base 10 is located within the orthographic projection of the pattern surrounded and defined by the contour of a via K1 within another virtual quadrilateral adjacent to the virtual quadrilateral Q on the base 10. For example, the virtual quadrilateral Q further includes a third virtual quadrilateral Q. The third virtual quadrilateral Q and the second virtual quadrilateral Q2 are sequentially arranged along the first direction X. The second virtual quadrilateral Q2 and the third virtual quadrilateral share the same third electrode 313. The orthographic projection of one of the two third electrode connection portions 53 on the base 10 is located within the orthographic projection of the pattern surrounded and defined by the contour of the via K1 within the second virtual quadrilateral Q2 on the base 10. The orthographic projection of the other third electrode connection portion 53 on the base 10 is located within the orthographic projection of the pattern surrounded and defined by the contour of the via K1 within the third virtual quadrilateral Q on the base 10.

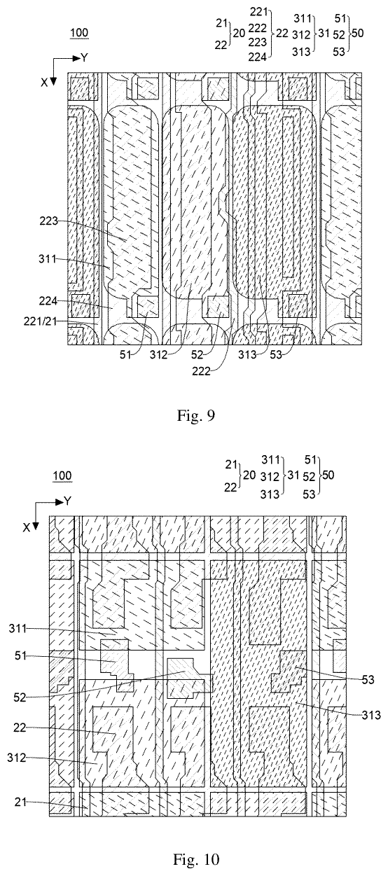

FIG. 8 is a partially enlarged schematic structural view of another array substrate 100 according to an embodiment of the present application. FIG. 9 is a partially enlarged schematic structural view of another array substrate 100 according to an embodiment of the present application.

In some optional embodiments, as shown in FIG. 8 and FIG. 9, the first electrode 311, the second electrode 312, and the third electrode 313 are sequentially spaced apart and extend along the same direction.

Optionally, as shown in FIG. 9, the first electrode 311, the second electrode 312, and the third electrode 313 may be spaced apart along the second direction Y, and the first electrode 311, the second electrode 312, and the third electrode 313 all extend along the first direction X. Or, as shown in FIG. 8, the first electrode 311, the second electrode 312, and the third electrode 313 may be spaced apart along the first direction X, and the first electrode 311, the second electrode 312, and the third electrode 313 all extend along the second direction Y. It is obvious that the first electrode 311, the second electrode 312, and the third electrode 313 may also be arranged along other directions.

By the above arrangement, the embodiment of the present application is conducive to simplifying the arrangement of the pixel electrodes 31, thereby reducing the manufacturing difficulty of the pixel electrodes 31 and improving the manufacturing yield of the array substrate 100.

In some optional embodiments, as shown in FIG. 8, an extension direction of each of the constant signal line 22 and the non-constant signal line 21 intersects an extension direction of the first electrode 311, the second electrode 312, and the third electrode 313. The orthographic projections of the first electrode 311, the second electrode 312, and the third electrode 313 on the base 10 are all overlapped with an orthographic projection of the same constant signal line 22 on the base 10; and/or the orthographic projections of the first electrode 311, the second electrode 312, and the third electrode 313 on the base 10 are all overlapped with an orthographic projection of the same non-constant signal line 21 on the base 10.

Optionally, the extension direction of the constant signal line 22 and the non-constant signal line 21 is the first direction X, and the extension direction of the first electrode 311, the second electrode 312, and the third electrode 313 is the second direction Y. Or, the extension direction of the constant signal line 22 and the non-constant signal line 21 is the second direction Y, and the extension direction of the first electrode 311, the second electrode 312, and the third electrode 313 is the first direction X.

In some embodiments, the orthographic projections of the first electrode 311, the second electrode 312, and the third electrode 313 on the base 10 are all overlapped with the orthographic projection of the same constant signal line 22 on the base 10, and the orthographic projections of the first electrode 311, the second electrode 312, and the third electrode 313 on the base 10 are all overlapped with the orthographic projection of the same non-constant signal line 21 on the base 10. In other embodiments, the orthographic projections of the first electrode 311, the second electrode 312, and the third electrode 313 on the base 10 are all overlapped with the orthographic projection of the same constant signal line 22 on the base 10. In still other embodiments, the orthographic projections of the first electrode 311, the second electrode 312, and the third electrode 313 on the base 10 are all overlapped with the orthographic projection of the same non-constant signal line 21 on the base 10.

Optionally, the number of constant signal lines 22 whose orthographic projections on the base 10 overlap with the orthographic projections of the first electrode 311, the second electrode 312, and the third electrode 313 on the base 10 may be one or more. For example, the orthographic projections of a plurality of constant signal lines 22 on the base 10 all overlap with the orthographic projections of the first electrode 311, the second electrode 312, and the third electrode 313 on the base 10.

Optionally, the number of non-constant signal lines 21 whose orthographic projections on the base 10 overlap with the orthographic projections of the first electrode 311, the second electrode 312, and the third electrode 313 on the base 10 may be one or more. For example, the orthographic projections of a plurality of non-constant signal lines 21 on the base 10 all overlap with the orthographic projections of the first electrode 311, the second electrode 312, and the third electrode 313 on the base 10.

By the above arrangement, the embodiment of the present application allows one constant signal line 22 to be arranged below the first electrode 311, the second electrode 312, and the third electrode 313 during the wiring process, thereby increasing the wiring area of the constant signal line 22 and increasing the overlapping area between the constant signal line and the pixel electrode 31. At the same time, arranging one non-constant signal line 21 below the first electrode 311, the second electrode 312, and the third electrode 313 during the wiring process can increase the wiring area of the non-constant signal line 21, increase the design flexibility of the circuit, and improve the application range of the array substrate 100.

In some optional embodiments, the constant signal lines 22 include a first constant signal line 221 and a second constant signal line 222. The non-constant signal lines 21 include a first non-constant signal line 211. The first constant signal line 221, the second constant signal line 222, and the first non-constant signal line 211 all extend along the first direction X and are spaced apart along the second direction Y. One first constant signal line 221 is disposed between any two adjacent lines selected from the first non-constant signal line 211 corresponding to the first electrode 311, the first non-constant signal line 211 corresponding to the second electrode 312, the first non-constant signal line 211 corresponding to the third electrode 313, and the second constant signal line 222.

For example, the first non-constant signal line 211 corresponding to the first electrode 311, the first non-constant signal line 211 corresponding to the second electrode 312, the first non-constant signal line 211 corresponding to the third electrode 313, and the second constant signal line 222 are sequentially spaced apart along the second direction Y. And one first constant signal line 221 is disposed between the first non-constant signal line 211 corresponding to the first electrode 311 and the first non-constant signal line 211 corresponding to the second electrode 312, one first constant signal line 221 is disposed between the first non-constant signal line 211 corresponding to the second electrode 312 and the first non-constant signal line 211 corresponding to the third electrode 313, and one first constant signal line 221 is disposed between the first non-constant signal line 211 corresponding to the third electrode 313 and the second constant signal line 222.

In some optional embodiments, the orthographic projection of the first non-constant signal line 211 corresponding to the first electrode 311 on the base 10 and the orthographic projection of the second constant signal line 222 on the base 10 are symmetrically arranged about a center line of the orthographic projection of the first electrode 311 on the base 10 along the first direction X; and/or the orthographic projection of the first non-constant signal line 211 corresponding to the second electrode 312 on the base 10 and the orthographic projection of the first non-constant signal line 211 corresponding to the third electrode 313 on the base 10 are symmetrically arranged about the center line of the orthographic projection of the first electrode 311 on the base 10 along the first direction X.

Optionally, the center line of the first electrode 311 along the first direction X may be the center line of the second electrode 312 along the first direction X, or may be the center line of the third electrode 313 along the first direction X.

In some optional embodiments, the orthographic projections of the first constant signal line 221 corresponding to the first electrode 311, the first constant signal line 221 corresponding to the second electrode 312, and the first constant signal line 221 corresponding to the third electrode 313 on the base 10 are sequentially arranged along the second direction Y. The orthographic projection of the first constant signal line 221 corresponding to the second electrode 312 on the base 10 passes through the center line of the orthographic projection of the first electrode 311 on the base 10 along the first direction X and is symmetrically arranged about the center line of the orthographic projection of the first electrode 311 on the base 10 along the first direction X. The orthographic projection of the first constant signal line 221 corresponding to the first electrode 311 on the base 10 and the orthographic projection of the first constant signal line 221 corresponding to the third electrode 313 on the base 10 are symmetrically arranged about the center line of the orthographic projection of the first electrode 311 on the base 10 along the first direction X.

Optionally, the light-emitting units 70 corresponding to the first electrode 311, the second electrode 312, and the third electrode 313 may form a pixel unit. Along the second direction Y, a light-transmitting region may be formed between two adjacent pixel units. Optionally, the display panel 200 may include a light-transmitting area. In the light-transmitting area, the light-transmitting region between two adjacent pixels may be used for light transmission.

In some optional embodiments, as shown in FIG. 9, an extension direction of each of the constant signal line 22 and the non-constant signal line 21 is the same as an extension direction of the first electrode 311, the second electrode 312, and the third electrode 313. Orthographic projections of at least two of the first electrode 311, the second electrode 312, and the third electrode 313 on the base 10 are respectively overlapped with orthographic projections of different constant signal lines 22 on the base 10; and/or orthographic projections of at least two of the first electrode 311, the second electrode 312, and the third electrode 313 on the base 10 are respectively overlapped with orthographic projections of different non-constant signal lines 21 on the base 10.

Optionally, the extension direction of the constant signal line 22 and the non-constant signal line 21 is the first direction X, and the extension direction of the first electrode 311, the second electrode 312, and the third electrode 313 is the first direction X. Or, the extension direction of the constant signal line 22 and the non-constant signal line 21 is the second direction Y, and the extension direction of the first electrode 311, the second electrode 312, and the third electrode 313 is the second direction Y.

For example, a plurality of constant signal lines 22 are spaced apart along the second direction Y, and the plurality of constant signal lines 22 along the second direction Y are, in order, a first constant signal line 22, a second constant signal line 22, and a third constant signal line 22. The first electrode 311, the second electrode 312, and the third electrode 313 are sequentially arranged along the second direction Y. The orthographic projection of the first electrode 311 on the base 10 overlaps with the orthographic projection of the first constant signal line 22 on the base 10. The orthographic projection of the second electrode 312 on the base 10 overlaps with the orthographic projection of the first constant signal line 22 on the base 10. The orthographic projection of the third electrode 313 on the base 10 overlaps with the orthographic projection of the second constant signal line 22 on the base 10. Or, the orthographic projection of the first electrode 311 on the base 10 overlaps with the orthographic projection of the first constant signal line 22 on the base 10. The orthographic projection of the second electrode 312 on the base 10 overlaps with the orthographic projection of the second constant signal line 22 on the base 10. The orthographic projection of the third electrode 313 on the base 10 overlaps with the orthographic projection of the second constant signal line 22 on the base 10. Or, the orthographic projection of the first electrode 311 on the base 10 overlaps with the orthographic projection of the first constant signal line 22 on the base 10. The orthographic projection of the second electrode 312 on the base 10 overlaps with the orthographic projection of the second constant signal line 22 on the base 10. The orthographic projection of the third electrode 313 on the base 10 overlaps with the orthographic projection of the third constant signal line 22 on the base 10.

For example, a plurality of non-constant signal lines 21 are spaced apart along the second direction Y, and the plurality of non-constant signal lines 21 along the second direction Y are, in order, a first non-constant signal line 21, a second non-constant signal line 21, and a third non-constant signal line 21. The first electrode 311, the second electrode 312, and the third electrode 313 are sequentially arranged along the second direction Y. The orthographic projection of the first electrode 311 on the base 10 overlaps with the orthographic projection of the first non-constant signal line 21 on the base 10. The orthographic projection of the second electrode 312 on the base 10 overlaps with the orthographic projection of the first non-constant signal line 21 on the base 10. The orthographic projection of the third electrode 313 on the base 10 overlaps with the orthographic projection of the second non-constant signal line 21 on the base 10. Or, the orthographic projection of the first electrode 311 on the base 10 overlaps with the orthographic projection of the first non-constant signal line 21 on the base 10. The orthographic projection of the second electrode 312 on the base 10 overlaps with the orthographic projection of the second non-constant signal line 21 on the base 10. The orthographic projection of the third electrode 313 on the base 10 overlaps with the orthographic projection of the second non-constant signal line 21 on the base 10. Or, the orthographic projection of the first electrode 311 on the base 10 overlaps with the orthographic projection of the first non-constant signal line 21 on the base 10. The orthographic projection of the second electrode 312 on the base 10 overlaps with the orthographic projection of the second non-constant signal line 21 on the base 10. The orthographic projection of the third electrode 313 on the base 10 overlaps with the orthographic projection of the third non-constant signal line 21 on the base 10.

In some embodiments, the orthographic projections of at least two of the first electrode 311, the second electrode 312, and the third electrode 313 on the base 10 are respectively overlapped with the orthographic projections of different constant signal lines 22 on the base 10; and the orthographic projections of at least two of the first electrode 311, the second electrode 312, and the third electrode 313 on the base 10 are respectively overlapped with the orthographic projections of different non-constant signal lines 21 on the base 10. In other embodiments, the orthographic projections of at least two of the first electrode 311, the second electrode 312, and the third electrode 313 on the base 10 are respectively overlapped with the orthographic projections of different constant signal lines 22 on the base 10. In still other embodiments, the orthographic projections of at least two of the first electrode 311, the second electrode 312, and the third electrode 313 on the base 10 are respectively overlapped with the orthographic projections of different non-constant signal lines 21 on the base 10.

Through the above arrangement, the embodiment of the present application reduces the size of the pixel electrode 31 in the arrangement direction and increases the size of the pixel electrode 31 in its own extension direction, thereby increasing the overlapping area between the pixel electrode 31 and a single constant signal line 22 and increasing the overlapping area between the pixel electrode 31 and a single non-constant signal line 21, reducing the capacitive coupling effect between the pixel electrode 31 and different constant signal lines 22, further reducing the possibility of crosstalk between the non-constant signal line 21 and the pixel electrode 31, improving the display effect of the corresponding light-emitting unit 70, and improving the reliability of the display panel.

In some optional embodiments, the constant signal lines 22 include a first constant signal line 221 and a second constant signal line 222. The non-constant signal lines 21 include a first non-constant signal line 211. The first constant signal line 221, the second constant signal line 222, and the first non-constant signal line 211 all extend along the first direction X and are spaced apart along the second direction Y. The orthographic projection of the first constant signal line 221 corresponding to the first electrode 311 or the second electrode 312 on the base 10 passes through a center line of the orthographic projection of the first electrode 311 or the second electrode 312 on the base 10 along the first direction X and is symmetrically arranged about the center line of the orthographic projection of the first electrode 311 or the second electrode 312 on the base 10 along the first direction X.

For example, the orthographic projection of the first constant signal line 221 corresponding to the first electrode 311 on the base 10 passes through the center line of the orthographic projection of the first electrode 311 on the base 10 along the first direction X, and the orthographic projection of this first constant signal line 221 on the base 10 is symmetrically arranged about the center line of the orthographic projection of the first electrode 311 on the base 10 along the first direction X. And/or, the orthographic projection of the first constant signal line 221 corresponding to the second electrode 312 on the base 10 passes through the center line of the orthographic projection of the second electrode 312 on the base 10 along the first direction X, and the orthographic projection of this first constant signal line 221 on the base 10 is symmetrically arranged about the center line of the orthographic projection of the second electrode 312 on the base 10 along the first direction X.

In some optional embodiments, the orthographic projection of the first non-constant signal line 211 corresponding to the second electrode 312 on the base 10 and the orthographic projection of the second constant signal line 222 overlapping with the orthographic projection of the second electrode 312 on the base 10 are symmetrically arranged about the center line of the orthographic projection of the second electrode 312 on the base 10 along the first direction X.

For example, the orthographic projection of one second constant signal line 222 on the base 10 overlaps with the orthographic projection of the second electrode 312 on the base 10, and the overlapping portion of the orthographic projection of this second constant signal line 222 on the base 10 and the orthographic projection of the second electrode 312 on the base 10 and the first non-constant signal line 211 corresponding to the second electrode 312 are symmetrically arranged about the center line of the orthographic projection of the second electrode 312 on the base 10 along the first direction X.

In some embodiments, the second constant signal line 222 has a mesh structure. For example, a portion of the plurality of second constant signal lines 222 extend along the first direction X, and another portion of the plurality of second constant signal lines 222 extend along the second direction Y. The second constant signal lines 222 extending along the first direction X are in the same layer as the first constant signal line 221. The second constant signal lines 222 extending along the second direction Y are in a different layer from the second constant signal lines 222 extending along the first direction X. A via structure may be provided between the second constant signal lines 222 extending along the second direction Y and the second constant signal lines 222 extending along the first direction X. The via structure may be located in the overlapping region between the second constant signal line 222 and the pixel electrode 31. The symmetry of the second constant signal line 222 with other signal lines about the center line of the pixel electrode 31 along the first direction X refers to the extending structure of the second constant signal line 222, excluding the via structure. Similarly, the first non-constant signal line 211 and the first constant signal line 221 may also include via structures. The symmetry of the first non-constant signal line 211 and the first constant signal line 221 with other signal lines about the center line of the orthographic projection of the pixel electrode 31 on the base 10 along the first direction X is the same as that of the second constant signal line 222 with other signal lines.

In some optional embodiments, a distance between the orthographic projection of the first non-constant signal line 211 corresponding to the second electrode 312 on the base 10 and the center line of the orthographic projection of the second electrode 312 on the base 10 along the first direction X is equal to a distance between the orthographic projection of the second constant signal line 222 overlapping with the orthographic projection of the second electrode 312 on the base 10 and the center line of the orthographic projection of the second electrode 312 on the base 10 along the first direction X.

In some optional embodiments, the first constant signal line 221 corresponding to the third electrode 313 includes a first branch, a second branch, and a connection line. The first branch and the second branch both extend along the first direction X and are spaced apart along the second direction Y. The first branch and the second branch are connected by the connection line. The orthographic projection of the third electrode 313 on the base 10 overlaps with the orthographic projection of the first non-constant signal line 211 for driving the pixel circuit of the first electrode 311 on the base 10. The orthographic projection of the first branch on the base 10 passes through the center line of the orthographic projection of the third electrode 313 on the base 10 along the first direction X and is symmetrically arranged about the center line of the orthographic projection of the third electrode 313 on the base 10 along the first direction X. The orthographic projection of the first non-constant signal line 211 corresponding to the third electrode 313 on the base 10 and the orthographic projection of the second branch on the base 10 are symmetrically arranged about the center line of the orthographic projection of the third electrode 313 on the base 10 along the first direction X. The orthographic projection of the second constant signal line 222 overlapping with the orthographic projection of the third electrode 313 on the base 10 on the base 10 and the orthographic projection of the first non-constant signal line 211 for driving the pixel circuit of the first electrode 311 on the base 10 are symmetrically arranged about the center line of the orthographic projection of the third electrode 313 on the base 10 along the first direction X.

Optionally, the orthographic projection of one first branch on the base 10, the orthographic projection of one second branch on the base 10, and the orthographic projection of the connection line on the base 10 all overlap with the orthographic projection of the same third electrode 313 on the base 10. Optionally, one first branch, one second branch, and the connection line for connecting the first branch and the second branch form a repeating structure. One first constant signal line 221 may include a plurality of repeating structures. One constant signal line 22 is connected to a plurality of pixel circuits driving the third electrode 313. The plurality of repeating structures and the plurality of third electrodes 313 are arranged in one-to-one correspondence.

Optionally, one first branch and one second branch may be connected by one or more connection lines.

For example, the orthographic projection of the first branch on the base 10 passes through the center line of the orthographic projection of the third electrode 313 on the base 10 along the first direction X, and the orthographic projection of the first branch on the base 10 is symmetrically arranged about the center line of the orthographic projection of the third electrode 313 on the base 10 along the first direction X.

Through the above arrangement, the embodiment of the present application is conducive to achieving symmetrical arrangement of the signal lines on the side of the third electrode 313 facing the base 10, improving the flatness of the third electrode 313, and reducing the possibility of color shift of the light-emitting unit 70 corresponding to the third electrode 313 at different viewing angles.

In some optional embodiments, an overlapping area between the orthographic projection of the first electrode 311 and the orthographic projection of the first constant signal line 221 on the base 10 is greater than an overlapping area between the orthographic projection of the second electrode 312 and the orthographic projection of the first constant signal line 221 on the base 10. And the overlapping area between the orthographic projection of the second electrode 312 and the orthographic projection of the first constant signal line 221 on the base 10 is greater than an overlapping area between the orthographic projection of the third electrode 313 and the orthographic projection of the first constant signal line 221 on the base 10.

In some optional embodiments, the light-emitting units 70 corresponding to the first electrode 311, the second electrode 312, and the third electrode 313 form a pixel unit. The arrangement of the constant signal line 22 and the non-constant signal line 21 corresponding to the pixel unit is the same as the arrangement of the pixel unit.

For example, a plurality of pixel units are arranged in an array along the first direction X and the second direction Y. The constant signal line 22 corresponding to the first electrode 311, the non-constant signal line 21 corresponding to the first electrode 311, the constant signal line 22 corresponding to the second electrode 312, the non-constant signal line 21 corresponding to the second electrode 312, the constant signal line 22 corresponding to the third electrode 313, and the non-constant signal line 21 corresponding to the third electrode 313 form a sub-unit arranged in an array along the first direction X and the second direction Y.

FIG. 10 is a partially enlarged schematic structural view of another array substrate 100 according to an embodiment of the present application.

In some optional embodiments, as shown in FIG. 10, the first electrode 311 and the second electrode 312 are spaced apart along the first direction X. The third electrode 313 is located on the same side of the adjacent first electrode 311 and second electrode 312 along the second direction Y. And the third electrode 313 is spaced apart from the adjacent first electrode 311 and second electrode 312 along the second direction Y. The first direction X, the second direction Y, and the thickness direction Z of the array substrate 100 intersect pairwise.

For example, the first electrode 311, the second electrode 312, and the third electrode 313 are arranged in a triangular pattern.

Optionally, the area of the third electrode may be greater than or equal to the sum of the areas of the first electrode 311 and the second electrode 312.

By the above arrangement, the embodiment of the present application is conducive to increasing the arrangement of the corresponding light-emitting units 70, improving the design flexibility of the light-emitting units, and improving the application range of the display panel.

In some optional embodiments, the constant signal lines 22 include a first constant signal line 221. The first constant signal line 221 extends along the first direction X. An overlapping area between the orthographic projection of the first electrode 311 and the orthographic projection of the first constant signal line 221 on the base 10 is less than an overlapping area between the orthographic projection of the second electrode 312 and the orthographic projection of the first constant signal line 221 on the base 10. And the overlapping area between the orthographic projection of the second electrode 312 and the orthographic projection of the first constant signal line 221 on the base 10 is less than an overlapping area between the orthographic projection of the third electrode 313 and the orthographic projection of the first constant signal line 221 on the base 10.

Optionally, the orthographic projection of the first electrode 311 on the base 10 may overlap with the orthographic projection of the first constant signal line 221 for driving the pixel circuit of the first electrode 311 on the base 10. The orthographic projection of the first electrode 311 on the base 10 may also overlap with the orthographic projection of the first constant signal line 221 for driving the pixel circuit of the second electrode 312 on the base 10. It can be understood that under the condition that the orthographic projection of the first electrode 311 on the base 10 overlaps with both the orthographic projection of the first constant signal line 221 for driving the pixel circuit of the first electrode 311 and the orthographic projection of the first constant signal line 221 for driving the pixel circuit of the second electrode 312, the sum of the two overlapping areas is the overlapping area between the first electrode 311 and the first constant signal line 221 on the base 10.

Optionally, the orthographic projection of the second electrode 312 on the base 10 may overlap with the orthographic projection of the first constant signal line 221 for driving the pixel circuit of the second electrode 312 on the base 10. The orthographic projection of the second electrode 312 on the base 10 may also overlap with the orthographic projection of the first constant signal line 221 for driving the pixel circuit of the first electrode 311 on the base 10. It can be understood that under the condition that the orthographic projection of the first electrode 311 on the base 10 overlaps with both the orthographic projection of the first constant signal line 221 for driving the pixel circuit of the first electrode 311 and the orthographic projection of the first constant signal line 221 for driving the pixel circuit of the second electrode 312, the sum of the two overlapping areas is the overlapping area between the second electrode 312 and the first constant signal line 221 on the base 10.

In some optional embodiments, the first constant signal line 221 includes a surface signal portion 221a. An area of the surface signal portion 221a corresponding to the first electrode 311 is equal to an area of the surface signal portion 221a corresponding to the second electrode 312. And the area of the surface signal portion 221a corresponding to the first electrode 311 is less than an area of the surface signal portion 221a corresponding to the third electrode 313.

It can be understood that the area of the surface signal portion 221a corresponding to the second electrode 312 is less than the area of the surface signal portion 221a corresponding to the third electrode 313.

In some optional embodiments, an orthographic projection of a portion of the surface signal portion 221a corresponding to the first electrode 311 on the base 10 overlaps with the orthographic projection of the first electrode 311 on the base 10. An orthographic projection of another portion of the surface signal portion 221a corresponding to the first electrode 311 on the base 10 overlaps with the orthographic projection of the second electrode 312 on the base 10.

In some optional embodiments, an orthographic projection of the surface signal portion 221a corresponding to the second electrode 312 on the base 10 overlaps with each of the orthographic projections of the first electrode 311, the second electrode 312, and the third electrode 313 on the base 10.

For example, one surface signal portion 221a includes three regions. One region of the orthographic projection on the base 10 overlaps with the orthographic projection of the first electrode 311 on the base 10. Another region of the orthographic projection on the base 10 overlaps with the orthographic projection of the second electrode 312 on the base 10. The last region of the orthographic projection on the base 10 overlaps with the orthographic projection of the third electrode 313 on the base 10.

In some optional embodiments, surface signal portions 221a corresponding to the same type of pixel electrode 31 in adjacent pixel electrodes are connected to form an integral planar structure.

For example, the surface signal portion 221a corresponding to one third electrode 313 is connected to the surface signal portion 221a corresponding to an adjacent third electrode 313 to form an integral planar structure.

Optionally, the surface signal portion 221a corresponding to one third electrode 313 may include a plurality. For example, one third electrode 313 corresponds to two surface signal portions 221a. The area of one of the two surface signal portions 221a corresponding to the third electrode 313 may be greater than the area of the surface signal portion 221a corresponding to the first electrode 311. The area of the other of the two surface signal portions 221a corresponding to the third electrode 313 may be equal to the area of the surface signal portion 221a that overlaps with the orthographic projection of the first electrode 311 on the base 10 and is used for driving the pixel circuit of the second electrode 312. And/or, the area of one of the two surface signal portions 221a corresponding to the third electrode 313 may be greater than the area of the surface signal portion 221a corresponding to the second electrode 312. The area of the other of the two surface signal portions 221a corresponding to the third electrode 313 may be equal to the area of the surface signal portion 221a that overlaps with the orthographic projection of the second electrode 312 on the base 10 and is used for driving the pixel circuit of the first electrode 311.

In some optional embodiments, as shown in FIG. 7 to FIG. 10, the constant signal line 22 includes a connected first portion 223 and a second portion 224. A dimension of the first portion 223 along its own width direction is greater than a dimension of the second portion 224 along its own width direction. The orthographic projection of the first portion 223 on the base 10 at least partially overlaps with the orthographic projection of the pixel electrode 31 on the base 10.

In some embodiments, the orthographic projection of the first portion 223 on the base 10 overlaps with the orthographic projection of the pixel electrode 31 on the base 10. In other embodiments, a portion of the orthographic projection of the first portion 223 on the base 10 overlaps with a portion of the orthographic projection of the pixel electrode 31 on the base 10.

In some embodiments, the first portion 223 includes the surface signal portion 221a, and the second portion 224 includes the connection portion 221b.

In some embodiments, the number of first portions 223 may include a plurality. Adjacent first portions are connected by the second portion 224.

In the embodiment of the present application, by setting the first portion 223, the overlapping area between the constant signal line 22 and the pixel electrode 31 is further increased, and combined with different pixel electrode arrangements, the capacitive coupling effect between the constant signal line 22 and the pixel electrode 31 in array substrates 100 with different design requirements can be enhanced. By setting the second portion 224, the space occupied by the constant signal line 22 in the array substrate 100 is adaptively reduced, the wiring design flexibility of the constant signal line 22 is improved, and the application range of the array substrate 100 is improved.

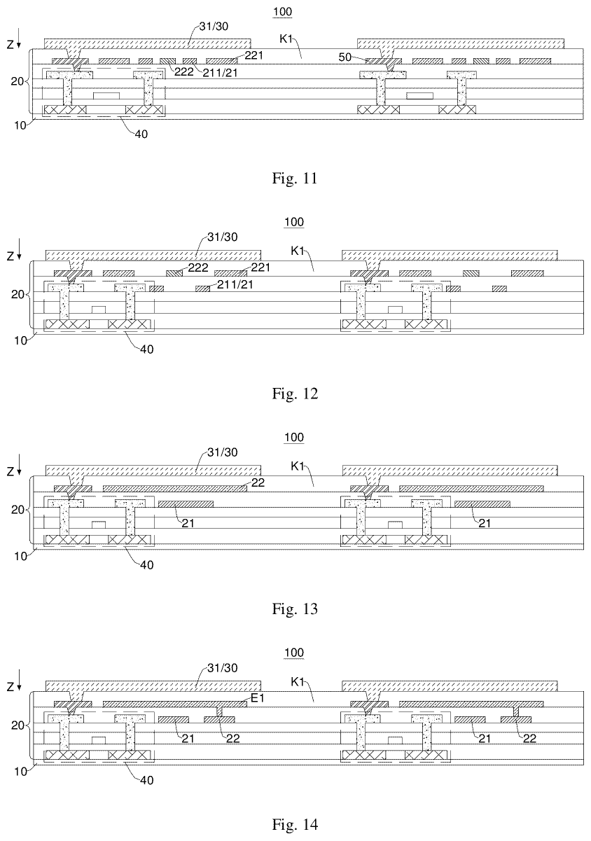

FIG. 11 is a schematic cross-sectional structural view of another array substrate 100 according to an embodiment of the present application.

In some optional embodiments, as shown in FIG. 7 and FIG. 11, the constant signal line 22 and the non-constant signal line 21 are disposed in the same layer, thereby reducing the number of layers in the signal line layer group 20, reducing the overall thickness of the array substrate 100, and achieving a thinner and lighter display panel.

Optionally, the signal line layer group 20 includes multiple signal line layers. For example, the signal line layer group includes four layers, which are, in order from the side away from the base 10, a first signal line layer, a second signal line layer, a third signal line layer, and a fourth signal line layer. The constant signal line 22 and the non-constant signal line 21 are located in the fourth signal line layer.

FIG. 12 is a schematic cross-sectional structural view of another array substrate 100 according to an embodiment of the present application.

In some optional embodiments, as shown in FIG. 7 and FIG. 12, a distance between the pixel electrode 31 and the non-constant signal line 21 is greater than a distance between the pixel electrode 31 and the constant signal line 22.

For example, the non-constant signal line 21 and the constant signal line 22 are located in different layers of the signal line layer group 20. For example, the constant signal line 22 is located in the third signal line layer, and the non-constant signal line 21 is located in the fourth signal line layer.

By the above arrangement, the embodiment of the present application is conducive to increasing the distance between the non-constant signal line 21 and the pixel electrode 31, thereby reducing the capacitance between the non-constant signal line 21 and the pixel electrode 31, further reducing the capacitive coupling effect between the non-constant signal line 21 and the pixel electrode 31, reducing the possibility of crosstalk between the non-constant signal line 21 and the pixel electrode 31, and improving the reliability of the array substrate 100.

FIG. 13 is a schematic cross-sectional structural view of another array substrate 100 according to an embodiment of the present application.

In some optional embodiments, as shown in FIG. 13, the non-constant signal line 21 is located between the constant signal line 22 and the base 10.

Optionally, the non-constant signal line 21 is located between the constant signal line 22 and the base 10, and the orthographic projection of the non-constant signal line 21 on the base 10 at least partially overlaps with the orthographic projection of the constant signal line on the base 10, so that the constant signal line 22 can serve a shielding function. The constant signal line 22 can effectively shield the electric field between the pixel electrode 31 and the non-constant signal line 21, reduce the impact of capacitive coupling between the pixel electrode and the non-constant signal line, and improve the reliability of the array substrate 100.

FIG. 14 is a schematic cross-sectional structural view of another array substrate 100 according to an embodiment of the present application.

In some optional embodiments, as shown in FIG. 14, a shielding structure E1 is disposed between the non-constant signal line 21 and the pixel electrode 31. The shielding structure is electrically connected to a constant voltage terminal.

Optionally, the non-constant signal line 21 and the constant signal line 22 are located in the same layer, and a shielding structure E1 is disposed between the non-constant signal line 21 and the pixel electrode 31, so that the shielding structure can effectively shield the electric field between the pixel electrode 31 and the non-constant signal line 21, reduce the impact of capacitive coupling between the pixel electrode and the non-constant signal line, and improve the reliability of the array substrate 100.

Optionally, the shielding structure E1 may be directly connected to the constant voltage terminal, or the shielding structure may be electrically connected to the constant voltage terminal through the constant signal line 22.

Optionally, the shielding structure E1 may be an integral planar structure or a block structure. For example, the shielding structure E1 may be a conductive block.

In some optional embodiments, a first insulation portion is disposed between the non-constant signal line 21 and the pixel electrode 31. A second insulation portion is disposed between the constant signal line and the pixel electrode. A dielectric constant of the first insulation portion is less than a dielectric constant of the second insulation portion.

Optionally, the dielectric constant of the insulating material can be adjusted by changing different insulating materials. For example, the material of the first insulation portion and the material of the second insulation portion are different.

Optionally, the first insulation portion and the second insulation portion may be located in the same film layer, or the first insulation portion and the second insulation portion may be located in different film layers. In some optional embodiments, a capacitance between the non-constant signal line 21 and the pixel electrode 31 is less than a capacitance between the constant signal line 22 and the pixel electrode 31.

By the above arrangement, the embodiment of the present application is conducive to reducing the capacitance between the non-constant signal line 21 and the pixel electrode 31, increasing the capacitance between the constant signal line 22 and the pixel electrode 31, thereby reducing the capacitive coupling effect between the non-constant signal line 21 and the pixel electrode, reducing the possibility of crosstalk between the non-constant signal line 21 and the pixel electrode 31, and improving the reliability of the array substrate 100.

In a second aspect, referring to FIG. 1, FIG. 2, and FIG. 8 to FIG. 10, an embodiment of the present application provides an array substrate 100. The array substrate 100 includes a base 10, a signal line layer group 20, and a first electrode layer 30. The signal line layer group 20 is located on a side of the base. The signal line layer group include a plurality of non-constant signal lines 21 and a plurality of constant signal lines. The non-constant signal line and the constant signal line both extend along a first direction X. The first electrode layer 30 is located on a side of the signal line layer group 20 away from the base 10. The first electrode layer includes a plurality of pixel electrodes 31. In a second direction intersecting the first direction X, at least a portion of an orthographic projection of the constant signal line 22 on the base 10 is located within an orthographic projection of one of the pixel electrodes 31 on the base 10, and at least a portion of an orthographic projection of an edge of the constant signal line 22 away from a centroid of the pixel electrode 31 on the base 10 is located within the orthographic projection of the corresponding pixel electrode 31 on the base 10.

In some embodiments, “at least a portion of the orthographic projection of the constant signal line 22 on the base 10 is located within the orthographic projection of the pixel electrode 31 on the base 10 along the width direction of the constant signal line 22” means that a portion or all of the orthographic projection of the constant signal line 22 on the base 10 along the second direction Y is located within the orthographic projection of the pixel electrode 31 on the base 10. Optionally, the width direction of the constant signal line 22 is parallel to the second direction Y.

Optionally, the constant signal line 22 includes a first edge and a second edge opposite to each other along its width direction. The first edge and the second edge are located on the same side of the centroid along the second direction Y, and the second edge is located on a side of the first edge away from the centroid. Along the second direction Y, the orthographic projection of the second edge on the base 10 is located within the orthographic projection of the pixel electrode 31 on the base 10. It is obvious that the orthographic projection of the first edge on the base 10 is also located within the orthographic projection of the pixel electrode 31 on the base 10.

The arrangements of the base, the signal line layer group 20, and the first electrode layer 30 are as described in the foregoing display panel embodiments and will not be repeated here.

In some optional embodiments, as shown in FIG. 5, a distance between adjacent two pixel electrodes 31 along the second direction Y is D. A minimum distance between the orthographic projection of the edge of the constant signal line 22 away from the centroid of the pixel electrode 31 on the base 10 and an orthographic projection of an edge of the pixel electrode 31 extending along the first direction X is d. D and d satisfy the relationship: 0.05≤d/D≤0.5.

For example, the edge of the pixel electrode 31 extending along the first direction X in its orthographic projection on the base 10 is a third edge. The minimum distance between the orthographic projection of the third edge on the base 10 and the orthographic projection of the second edge on the base 10 is d.

Optionally, the ratio of the minimum distance between the orthographic projection of the edge of the constant signal line 22 away from the centroid of the pixel electrode 31 on the base 10 and the orthographic projection of the edge of the pixel electrode 31 extending along the first direction X to the distance between adjacent two pixel electrodes 31 along the second direction is 0.05, 0.1, 0.3, or 0.5.

In the embodiment of the present application, by setting the ratio of the minimum distance between the orthographic projection of the edge of the constant signal line 22 away from the centroid of the pixel electrode 31 on the base 10 and the orthographic projection of the edge of the pixel electrode 31 extending along the first direction X to the distance between adjacent two pixel electrodes 31 along the second direction to be greater than or equal to 0.05, the distance between the pixel electrodes 31 is reduced, thereby reducing the distance between the light-emitting units 70 in the display panel and improving the resolution of the display panel. By setting the ratio to be less than or equal to 0.5, the area covered by the pixel electrode 31 on the constant signal line 22 is increased, thereby enhancing the capacitive coupling effect between the pixel electrode 31 and the constant signal line, improving the stability of the pixel electrode voltage, and thus improving the reliability of the array substrate 100.

In some optional embodiments, as shown in FIG. 3, the pixel electrodes 31 include a first electrode 311, a second electrode 312, and a third electrode 313. The first electrode, the second electrode, and the third electrode are respectively disposed corresponding to light-emitting units 70 of different colors.

The embodiment of the present application does not limit the colors of the light-emitting units 70 corresponding to the first electrode 311, the second electrode 312, and the third electrode 313. For example, the light-emitting units 70 include different colors, such as a red light-emitting unit, a green light-emitting unit, and a blue light-emitting unit 70. Optionally, the first electrode 311 may correspond to the red light-emitting unit 70, the second electrode 312 may correspond to the blue light-emitting unit 70, and the third electrode 313 may correspond to the green light-emitting unit 70. Optionally, the light-emitting units may further include a white light-emitting unit, and one of the first electrode 311, the second electrode 312, and the third electrode 313 may also correspond to the white light-emitting unit 70.

The embodiment of the present application does not limit the shapes and sizes of the first electrode 311, the second electrode 312, and the third electrode 313. For example, the shapes of the first electrode 311, the second electrode 312, and the third electrode 313 may be the same or different, or two of them may be the same, or all three may be different.

By the above arrangement, the embodiment of the present application is conducive to reducing the possibility of crosstalk between the pixel electrodes 31 corresponding to light-emitting units 70 of different colors and the non-constant signal line 21, improving the stability of the display effect of light-emitting units 70 of different colors, and thereby improving the reliability of the display panel.

In some optional embodiments, as shown in FIG. 1 to FIG. 4, centroids of one of the first electrodes 311, one of the second electrodes 312, and two of the third electrodes 313 are respectively disposed at four vertices of a virtual quadrilateral Q.

In other words, the centers of one adjacent first electrode 311, one second electrode 312, and two third electrodes 313 can be connected to form a virtual quadrilateral Q. In some embodiments, the first electrode 311 and the second electrode 312 may be disposed at two vertices facing each other among the vertices of the virtual quadrilateral Q. The two third electrodes 313 may be disposed at two vertices facing each other among the vertices of the virtual quadrilateral Q. The virtual quadrilateral may be a rectangle, rhombus, square, etc.

It can be understood that one of the first electrodes 311, one of the second electrodes 312, and two of the third electrodes 313 are respectively disposed at the four vertices of the virtual quadrilateral Q, and the light-emitting units 70 of corresponding colors are also disposed at the four vertices of the virtual quadrilateral Q, thereby forming the arrangement structure of sub-pixels in the display panel. Through this sub-pixel arrangement structure, color rendering driving can be performed by sharing adjacent sub-pixels, allowing high resolution to be achieved with a small number of pixels.

In some embodiments, as shown in FIG. 3, in a region corresponding to the virtual quadrilateral Q, the two third electrodes 313 are spaced apart along the first direction X, the first electrode 311 and the second electrode 312 are spaced apart along the second direction Y, and the first direction X, the second direction Y, and the thickness direction Z of the array substrate 100 intersect pairwise. Optionally, the first direction X, the second direction Y, and the thickness direction Z of the array substrate 100 are perpendicular to each other.

Within one virtual quadrilateral Q, that is, for one virtual quadrilateral, the two third electrodes 313 are spaced apart along the first direction X, the first electrode 311 and the second electrode 312 are spaced apart along the second direction Y, and at least a portion of the orthographic projection of the first electrode on a first plane and at least a portion of the orthographic projection of the second electrode 312 on the first plane are both located between the orthographic projections of the two third electrodes 313 on the first plane. The first plane is a plane perpendicular to the second direction Y. Optionally, the centroid of the first electrode 311 passes through a perpendicular line to the midpoint of the line connecting the centroids of the two third electrodes 313. The centroid of the second electrode 312 passes through a perpendicular line to the midpoint of the line connecting the centroids of the two third electrodes 313. Optionally, the line connecting the centroid of the first electrode 311 and the centroid of the second electrode 312 may be parallel to the second direction Y or may intersect the second direction Y.

In some optional embodiments, as shown in FIG. 2 to FIG. 4, the constant signal lines 22 include a first constant signal line 221 and a second constant signal line 222. The non-constant signal lines 21 include a first non-constant signal line 211. The first constant signal line 221, the second constant signal line 222, and the first non-constant signal line 211 all extend along the first direction X and are spaced apart along the second direction Y. An orthographic projection of at least one of the first constant signal line 221 and the second constant signal line 222 on the base 10 at least overlaps with an orthographic projection of the first electrode 311 on the base 10. An orthographic projection of at least one of the first constant signal line 221 and the second constant signal line 222 on the base 10 at least overlaps with an orthographic projection of the second electrode 312 on the base 10. And an orthographic projection of the first non-constant signal line 211 on the base 10 at least overlaps with the orthographic projection of the first electrode 311 on the base 10 and the orthographic projection of the second electrode 312 on the base 10.

Optionally, the functions of the first constant signal line 221 and the second constant signal line 222 are different.

Optionally, the number of first constant signal lines 221 may include one or more.

Optionally, the number of second constant signal lines 222 may include one or more.

Optionally, the number of first non-constant signal lines 211 may include one or more.

Optionally, the constant signal line 22 may further include a third constant signal line 22, a fourth constant signal line 22, or more.

Optionally, the non-constant signal line 21 may further include a second non-constant signal line 21, a third non-constant signal line 21, a fourth non-constant signal line 21, or more.

The embodiment of the present application does not limit the arrangement of the first constant signal line 221, the second constant signal line 222, and the third constant signal line. For example, the first constant signal line 221, the second constant signal line 222, and the third constant signal line may be alternately arranged along the second direction Y, or may be arranged according to a predetermined arrangement pattern based on actual design requirements.

In some embodiments, the orthographic projection of the first constant signal line 221 on the base 10 and the orthographic projection of the first non-constant signal line 211 on the base 10 overlap with the orthographic projection of the first electrode 311 on the base 10. Moreover, the orthographic projection of the first constant signal line 221 on the base 10 and the orthographic projection of the first non-constant signal line 211 on the base 10 overlap with the orthographic projection of the second electrode 312 on the base 10. In other embodiments, the orthographic projection of the second constant signal line 222 on the base 10 and the orthographic projection of the first non-constant signal line 211 on the base 10 overlap with the orthographic projection of the first electrode 311 on the base 10. Moreover, the orthographic projection of the second constant signal line 222 on the base 10 and the orthographic projection of the first non-constant signal line 211 on the base 10 overlap with the orthographic projection of the second electrode 312 on the base 10. In still other embodiments, the orthographic projection of the first constant signal line 221 on the base 10, the orthographic projection of the second constant signal line 222 on the base 10, and the orthographic projection of the first non-constant signal line 211 on the base 10 overlap with the orthographic projection of the first electrode 311 on the base 10. Moreover, the orthographic projection of the first constant signal line 221 on the base 10, the orthographic projection of the second constant signal line 222 on the base 10, and the orthographic projection of the first non-constant signal line 211 on the base 10 overlap with the orthographic projection of the second electrode 312 on the base 10. In other embodiments, the orthographic projection of at least one of the first constant signal line 221 and the second constant signal line 222 on the base 10 and the orthographic projection of the first non-constant signal line 211 on the base 10 may also at least partially overlap with the orthographic projection of the third electrode 313 on the base 10.

By the above arrangement, the embodiment of the present application is conducive to reducing the possibility of crosstalk between the non-constant signal line 21 and the pixel electrode 31, while increasing the flexibility of arranging the constant signal line 22 and the non-constant signal line 21, and improving the application range of the array substrate 100.

In some optional embodiments, the orthographic projection of the first constant signal line 221 on the base 10 and the orthographic projection of the second constant signal line 222 on the base 10 both overlap with the orthographic projection of the first electrode 311 on the base 10. Moreover, the orthographic projection of the first constant signal line 221 on the base 10 and the orthographic projection of the second constant signal line 222 on the base 10 both overlap with the orthographic projection of the second electrode 312 on the base 10.

In some optional embodiments, the second constant signal line 222 corresponding to the first electrode 311 or the second electrode 312 is disposed on both sides of the second constant signal line 222 corresponding to the same first electrode 311 or the same second electrode 312 along a width direction of the second constant signal line 222; and/or, the second constant signal line 222 corresponding to the first electrode 311 or the second electrode 312 is disposed on both sides of the second constant signal line 222 corresponding to the same first electrode 311 or the same second electrode 312 along the width direction of the second constant signal line 222.

The “corresponding” in the second constant signal line 222 corresponding to the first electrode 311 refers to the second constant signal line 222 configured to drive the first electrode 311, and the portion of the orthographic projection of this second constant signal line 222 on the base 10 that overlaps with the orthographic projection of this first electrode 311 on the base 10. Similarly, the “corresponding” in the first constant signal line 221 corresponding to the first electrode 311, the first non-constant signal line 211 corresponding to the first electrode 311, the first constant signal line 221 corresponding to the second electrode 312, the second constant signal line 222 corresponding to the second electrode 312, the first non-constant signal line 211 corresponding to the second electrode 312, the first constant signal line 221 corresponding to the third electrode 313, the second constant signal line 222 corresponding to the third electrode 313, and the first non-constant signal line 211 corresponding to the third electrode 313 is the same as the “corresponding” in the second constant signal line 222 corresponding to the first electrode 311, and will not be repeated.

In some embodiments, as shown in FIG. 4, the second constant signal line 222 corresponding to the first electrode 311 or the second electrode 312 is disposed on both sides along its own width direction with the first constant signal line 221 corresponding to the same first electrode 311 or the same second electrode 312. Moreover, the second constant signal line 222 corresponding to the first electrode 311 or the second electrode 312 is disposed on both sides along its own width direction with the first non-constant signal line 211 corresponding to the same first electrode 311 or the same second electrode 312. Optionally, two first non-constant signal lines 22, two first constant signal lines 221 may be arranged symmetrically with respect to the second constant signal line 222. For example, the arrangement of the two first non-constant signal lines 211, the two first constant signal lines 221, and the second constant signal line 222 along the second direction Y may be, in order: first constant signal line 221, first non-constant signal line 211, second constant signal line 222, first non-constant signal line 211, first constant signal line 221; or it may be: first non-constant signal line 22, first constant signal line 221, second constant signal line 222, first constant signal line 22, first non-constant signal line 211. It is obvious that the two first non-constant signal lines 22, two first constant signal lines 221 may also be arranged asymmetrically with respect to the second constant signal line 222. For example: first constant signal line 221, first non-constant signal line 211, second constant signal line 222, first constant signal line 221, first non-constant signal line 211.

In other embodiments, the second constant signal line 222 corresponding to the first electrode 311 or the same second electrode 312 is disposed on both sides along its own width direction with the first constant signal line 221 corresponding to the same first electrode 311 or the same second electrode 312. In still other embodiments, the second constant signal line 222 corresponding to the first electrode 311 or the second electrode 312 is disposed on both sides along its own width direction with the first non-constant signal line 211 corresponding to the same first electrode 311 or the same second electrode 312.

The width direction of the second constant signal line 222 may be a direction perpendicular to the extending direction of the second constant signal line.

In these optional embodiments, by arranging the first constant signal line 221 on both sides of the second constant signal line 222 along its width direction, it is conducive to increasing the overlapping area between the constant signal line 22 and the pixel electrode 31, thereby reducing the possibility of crosstalk between the non-constant signal line 21 and the pixel electrode. By arranging the first non-constant signal line 211 on both sides of the second constant signal line 222 along its width direction, it is conducive to improving the design flexibility of the first non-constant signal line and increasing the application range of the array substrate 100.

In some embodiments, a plurality of first constant signal lines 221 and/or a plurality of first non-constant signal lines 211 disposed on both sides of the second constant signal line 222 corresponding to the first electrode 311 or the second electrode 312 along its width direction have orthographic projections on the base 10 that are symmetrically arranged about a center line of the orthographic projection of the first electrode 311 on the base 10 along the first direction X.

For example, the number of first constant signal lines 221 is two, and the number of first non-constant signal lines 211 is two. The orthographic projections of the two first constant signal lines 221 on the base 10 are symmetrically arranged about the center line of the orthographic projection of the first electrode 311 on the base 10 along the first direction X. The orthographic projections of the two first non-constant signal lines 211 on the base 10 are symmetrically arranged about the center line of the orthographic projection of the first electrode 311 on the base 10 along the first direction X. Alternatively, the orthographic projection of one first constant signal line 221 on the base 10 and the orthographic projection of one first non-constant signal line 211 on the base 10 are symmetrically arranged about the center line of the orthographic projection of the first electrode 311 on the base 10 along the first direction X.

In some embodiments, the first non-constant signal line 211 corresponding to the first electrode 311 or the second electrode 312 includes a connected first segment 211a and a second segment 211b. The orthographic projection of the first segment 211a on the base 10 intersects a center line of the orthographic projection of the first electrode 311 or the second electrode 312 on the base 10 along the second direction Y. A minimum distance between an orthographic projection of the second segment 211b on the base 10 and an orthographic projection of the second constant signal line 222 adjacent to the second segment 211b on the base 10 is greater than a maximum distance between the orthographic projection of the first segment 211a on the base 10 and an orthographic projection of the second constant signal line 222 adjacent to the first segment 211a on the base 10.

It can be understood that the orthographic projections of the first segment 211a and the second segment 211b on the base 10 are both located within the orthographic projection of the first electrode 311 or the second electrode 312 on the base 10.

For example, the first non-constant signal line 211 corresponding to the first electrode 311 includes a connected first segment 211a and a second segment 211b. The orthographic projection of the first segment 211a on the base 10 intersects the center line of the orthographic projection of the first electrode 311 on the base 10 along the second direction Y. The minimum distance between the orthographic projection of the second segment 211b on the base 10 and the orthographic projection of the second constant signal line 222 adjacent to the second segment 211b on the base 10 is greater than the maximum distance between the orthographic projection of the first segment 211a on the base 10 and the orthographic projection of the second constant signal line 222 adjacent to the first segment 211a on the base 10. Or, the first non-constant signal line 211 corresponding to the second electrode 312 includes a connected first segment 211a and a second segment 211b. The orthographic projection of the first segment 211a on the base 10 intersects the center line of the orthographic projection of the second electrode 312 on the base 10 along the second direction Y. The minimum distance between the orthographic projection of the second segment 211b on the base 10 and the orthographic projection of the second constant signal line 222 adjacent to the second segment 211b on the base 10 is greater than the maximum distance between the orthographic projection of the first segment 211a on the base 10 and the orthographic projection of the second constant signal line 222 adjacent to the first segment 211a on the base 10. Optionally, under the condition that the orthographic projection of the second segment 211b on the base 10 and the orthographic projection of the adjacent second constant signal line 222 on the base 10 are designed with equal spacing, the minimum distance between the orthographic projection of the second segment 211b on the base 10 and the orthographic projection of the adjacent second constant signal line 222 on the base 10 is the distance between the orthographic projection of the second segment 211b on the base 10 and the orthographic projection of the adjacent second constant signal line 222 on the base 10. The second segment 211b and the adjacent second constant signal line 222 can also be designed with unequal spacing.

Optionally, the orthographic projection of the first segment 211a on the base 10 is parallel to the orthographic projection of the second constant signal line 222 on the base 10.

Optionally, the orthographic projection of the second segment 211b on the base 10 is parallel to the orthographic projection of the second constant signal line 222 on the base 10.

In some embodiments, an extension direction of the orthographic projection of the second segment 211b on the base 10 intersects an extension direction of the orthographic projection of the second constant signal line 222 on the base 10. And along a direction away from the centroid of the first electrode 311 or the second electrode 312, a distance between the orthographic projection of the second segment 211b on the base 10 and the orthographic projection of the adjacent second constant signal line 222 on the base 10 gradually increases.

Optionally, the orthographic projection of the second segment 211b on the base 10 may be a straight line inclined relative to the extension direction of the orthographic projection of the second constant signal line 222 on the base 10. The second segment 211b may also include a plurality of sub-segments. Along the direction away from the centroid of the first electrode 311 or the second electrode 312, the distance between the orthographic projections of the plurality of sub-segments on the base 10 and the orthographic projection of the adjacent constant signal line 22 on the base 10 gradually increases.

In some optional embodiments, the first non-constant signal line 211 corresponding to the first electrode 311 or the second electrode 312 further includes a third segment 211c. The third segment 211c is connected to an end of the first segment 211a away from the second segment 211b. A minimum distance between an orthographic projection of the third segment 211c on the base 10 and an orthographic projection of the second constant signal line 222 adjacent to the third segment 211c on the base 10 is greater than a maximum distance between the orthographic projection of the first segment 211a on the base 10 and the orthographic projection of the second constant signal line 222 adjacent to the first segment 211a on the base 10.

For example, the first non-constant signal line 211 corresponding to the first electrode 311 further includes a third segment 211c. The third segment 211c is connected to the end of the first segment 211a away from the second segment 211b. The minimum distance between the orthographic projection of the third segment 211c on the base 10 and the orthographic projection of the second constant signal line 222 adjacent to the third segment 211c on the base 10 is greater than the maximum distance between the orthographic projection of the first segment 211a on the base 10 and the orthographic projection of the second constant signal line 222 adjacent to the first segment 211a on the base 10. And/or, the first non-constant signal line 211 corresponding to the second electrode 312 further includes a third segment 211c. The third segment 211c is connected to the end of the first segment 211a away from the second segment 211b. The minimum distance between the orthographic projection of the third segment 211c on the base 10 and the orthographic projection of the second constant signal line 222 adjacent to the third segment 211c on the base 10 is greater than the maximum distance between the orthographic projection of the first segment 211a on the base 10 and the orthographic projection of the second constant signal line 222 adjacent to the first segment 211a on the base 10.

In some optional embodiments, the orthographic projection of the third segment 211c on the base 10 is parallel to the orthographic projection of the second constant signal line 222 on the base 10.

In some optional embodiments, a distance between the orthographic projection of the third segment 211c on the base 10 and the orthographic projection of the adjacent second constant signal line 222 on the base 10 gradually increases along a direction away from the centroid of the orthographic projection of the first electrode 311 or the second electrode 312 on the base 10.

For example, in a direction from the centroid of the first electrode 311 toward an edge of the first electrode 311 along the first direction X, the distance between the third segment 211c and the adjacent second constant signal line 222 gradually increases. And/or, in a direction from the centroid of the second electrode 312 toward an edge of the second electrode 312 along the first direction X, the distance between the third segment 211c and the adjacent second constant signal line 222 gradually increases. The “gradually increases” here may be a stepwise increase or a proportional increase. Through the above arrangement, a light-transmitting region can be formed between the second constant signal line 222 and the first non-constant signal line 211 to increase the light transmittance of the display panel 200.

In some embodiments, along the second direction Y, a distance between the orthographic projection of the second constant signal line 222 corresponding to the first electrode 311 or the second electrode 312 on the base 10 and the orthographic projection of the adjacent first non-constant signal line 211 on the base 10 is equal to a distance between the orthographic projection of the first non-constant signal line 211 corresponding to the first electrode 311 or the second electrode 312 on the base 10 and the orthographic projection of the adjacent first constant signal line 221 on the base 10.

For example, along the second direction Y, the distance between the orthographic projection of the second constant signal line 222 corresponding to the first electrode 311 on the base 10 and the orthographic projection of the adjacent first non-constant signal line 211 on the base 10 is equal to the distance between the orthographic projection of the first non-constant signal line 211 corresponding to the first electrode 311 on the base 10 and the orthographic projection of the adjacent first constant signal line 221 on the base 10. And/or, along the second direction Y, the distance between the orthographic projection of the second constant signal line 222 corresponding to the second electrode 312 on the base 10 and the orthographic projection of the adjacent first non-constant signal line 211 on the base 10 is equal to the distance between the orthographic projection of the first non-constant signal line 211 corresponding to the second electrode 312 on the base 10 and the orthographic projection of the adjacent first constant signal line 221 on the base 10. Through the above arrangement, it is conducive to increasing the flatness of the first electrode 311 and the second electrode 312, and reducing the possibility of color shift of the light-emitting units 70 corresponding to the first electrode 311 and the second electrode 312 at different viewing angles.

In some embodiments, the first constant signal line 221 includes a power line. For example, the power line may include a first power line for transmitting a power supply voltage to an anode and a second power line for transmitting a power supply voltage to a cathode. The first constant signal line 221 is at least one of the first power line and the second power line.

In some embodiments, the second constant signal line 222 includes an initialization voltage line. For example, the initialization voltage line may include a first initialization voltage line for resetting a gate of a thin film transistor 40 and a second initialization voltage line for resetting an anode. The second constant signal line 222 is at least one of the first initialization voltage line and the second initialization voltage line.

In some embodiments, the first non-constant signal line 211 includes a data line.

In some optional embodiments, as shown in FIG. 1 and FIG. 2, in a region corresponding to the virtual quadrilateral Q, the first constant signal line 221 is provided with a via K1. The orthographic projection of the pixel electrode 31 on the base 10 at least partially overlaps with an orthographic projection of a pattern surrounded and defined by a contour of the via K1 on the base 10.

Optionally, the first constant signal line 221 is provided with a closed via K1 structure. Optionally, the shape of the via may be circular, elliptical, rectangular, or other shapes.

Optionally, within one virtual quadrilateral Q, the number of vias K1 may be one or more.

It can be understood that within one virtual quadrilateral Q, portions of the first electrode 311, the second electrode 312, and the third electrode 313 extend toward the center of the virtual quadrilateral to occupy a portion of the area within the virtual quadrilateral. The orthographic projection of the first electrode 311 on the base 10 may at least partially overlap with the orthographic projection of the pattern surrounded and defined by the contour of the via K1 on the base 10. And/or, the orthographic projection of the second electrode 312 on the base 10 may at least partially overlap with the orthographic projection of the pattern surrounded and defined by the contour of the via K1 on the base 10. And/or, the orthographic projection of the third electrode 313 on the base 10 may at least partially overlap with the orthographic projection of the pattern surrounded and defined by the contour of the via K1 on the base 10. Taking the first electrode 311 as an example, “at least partially overlapping” here means that a portion of the orthographic projection of the first electrode on the base 10 overlaps with a portion of the orthographic projection of the pattern surrounded and defined by the contour of the via K1 on the base 10, or it may mean that the orthographic projection of the pattern surrounded and defined by the contour of the via on the base 10 falls within the orthographic projection of the first electrode 311 on the base 10.

The contour of the via K1 refers to the edge of the via K1 structure on the first constant signal line 221.

Optionally, the via may be located at the centroid of the virtual quadrilateral Q or at any position of the virtual quadrilateral.

In these optional embodiments, through the above arrangement, it is conducive to increasing the overlapping area between the pixel electrode 31 and the first constant signal line 221, thereby enhancing the capacitive coupling effect between the pixel electrode 31 and the constant signal line 22, reducing the possibility of crosstalk between the pixel electrode and the non-constant signal line 21, improving the reliability of the array substrate 100, and thereby improving the reliability of the display panel.

In some optional embodiments, as shown in FIG. 1 to FIG. 4, in a region corresponding to the virtual quadrilateral Q, the first constant signal line 221 includes a surface signal portion 221a and a connection portion 221b connected to each other. A dimension of the surface signal portion along the second direction Y is greater than a dimension of the connection portion 221b along the second direction. The surface signal portion 221a and the connection portion surround and define the via K1. The orthographic projection of the third electrode 313 on the base 10 at least partially overlaps with an orthographic projection of the surface signal portion 221a on the base 10.

Optionally, an orthographic projection of an edge of the surface signal portion 221a on the base 10 is at least partially located within the orthographic projection of the third electrode 313 on the base 10.

Optionally, the edge of the surface signal portion 221a includes a first edge L1 extending along the first direction X. At least a portion of an orthographic projection of the first edge L1 on the base 10 is located within the orthographic projection of the third electrode on the base 10.

Optionally, the orthographic projection of the first edge L1 on the base 10 is entirely located within the orthographic projection of the third electrode on the base 10.

Optionally, the first edge L1 is a straight edge.

Optionally, in a region corresponding to one virtual quadrilateral Q, the number of surface signal portions 221a may include one or more. Under the condition that only one surface signal portion 221a is provided in a region corresponding to one virtual quadrilateral Q, the surface signal portions 221a in adjacent regions corresponding to the virtual quadrilateral Q are connected by connection portions 221b. Under the condition that multiple surface signal portions 221a are provided in a region corresponding to one virtual quadrilateral Q, the multiple surface signal portions 221a in one region corresponding to the virtual quadrilateral Q are connected by connection portions 221b, and the surface signal portions 221a in adjacent regions corresponding to the virtual quadrilateral Q are connected by connection portions 221b. “In a region corresponding to the virtual quadrilateral” here refers to a region including one virtual quadrilateral and the surface signal portions, connection portions, and other structures corresponding to this virtual quadrilateral.

The surface signal portion 221a and the connection portion 221b surround and define the via K1. A portion of the edge of the surface signal portion and a portion of the edge of the connection portion form the contour of the via.

Optionally, a portion of the orthographic projection of the third electrode 313 on the base 10 overlaps with a portion of the orthographic projection of the surface signal portion 221a on the base 10; or the orthographic projection of the third electrode 313 on the base 10 falls within the orthographic projection of the surface signal portion 221a on the base 10; or the orthographic projection of the surface signal portion on the base 10 falls within the orthographic projection of the third electrode 313 on the base 10.

In some embodiments, in the region corresponding to the virtual quadrilateral Q, the two third electrodes 313 are spaced apart along the first direction X. By making the dimension of the surface signal portion 221a along the second direction Y greater than the dimension of the connection portion 221b along the second direction, the overlapping area between the surface signal portion 221a and the third electrode 313 on the base 10 is increased. At the same time, the dimension of the third electrode 313 along the first direction X is reduced, making the distance between the two third electrodes along the first direction smaller, thereby reducing the overall area of the virtual quadrilateral Q, and further reducing the area of the sub-pixels in the display panel, improving the resolution of the display panel.

As shown in FIG. 4, in the region corresponding to the virtual quadrilateral Q, the surface signal portions 221a include two surface signal portions, the two surface signal portions 221a are disposed on two sides of the via K1 along the first direction X, and the two surface signal portions 221a are disposed in one-to-one correspondence with the two third electrodes 313.

Optionally, the two surface signal portions 221a may be connected through one or more connection portions 221b.

In some optional embodiments, as shown in FIG. 2 and FIG. 5, in the region corresponding to the virtual quadrilateral Q, an orthographic projection of at least one of the first electrode 311 and the second electrode 312 on the base 10 overlaps with an orthographic projection of the connection portion 221b on the base 10.

In some embodiments, in the region corresponding to the virtual quadrilateral Q, the orthographic projection of the first electrode 311 on the base 10 overlaps with the orthographic projection of the connection portion 221b on the base 10, and the orthographic projection of the second electrode 312 on the base 10 overlaps with the orthographic projection of the connection portion 221b on the base 10. In other embodiments, in the region corresponding to the virtual quadrilateral Q, the orthographic projection of the first electrode 311 on the base 10 overlaps with the orthographic projection of the connection portion 221b on the base 10. In still other embodiments, in the region corresponding to the virtual quadrilateral Q, the orthographic projection of the second electrode 312 on the base 10 overlaps with the orthographic projection of the connection portion 221b on the base 10.

It can be understood that under the condition that the orthographic projections of both the first electrode 311 and the second electrode 312 on the base 10 overlap with the orthographic projection of the connection portion 221b on the base 10, the orthographic projection of the first electrode 311 on the base 10 and the orthographic projection of the second electrode 312 on the base 10 overlap with the orthographic projections of different connection portions 221b on the base 10, respectively.

Through the above setting, this embodiment is conducive to increasing the overlapping area between the first electrode 311 and/or the second electrode 312 and the constant signal line 22, thereby reducing the possibility of crosstalk between the first electrode 311 and/or the second electrode 312 and the non-constant signal line 21, and further reducing the possibility of display abnormalities of the light-emitting units 70 corresponding to the first electrode 311 and/or the second electrode 312, improving the reliability of the display panel.

In the region corresponding to the virtual quadrilateral Q, the connection portions 221b include two connection portions, the two connection portions 221b are disposed on two sides of the via K1 along the second direction Y, an orthographic projection of one of the two connection portions 221b on the base 10 at least partially overlaps with the orthographic projection of the first electrode 311 on the base 10, and an orthographic projection of the other of the two connection portions 221b on the base 10 at least partially overlaps with the orthographic projection of the second electrode 312 on the base 10.

Optionally, the two connection portions 221b may both be electrically connected to the surface signal portions 221a on both sides of the via K1 along the first direction X. Alternatively, only one connection portion 221b may electrically connect the surface signal portions 221a on both sides of the via K1 along the first direction X, and the other connection portion 221b may only be electrically connected to one of the two surface signal portions 221a on both sides of the via K1 along the first direction X, or the other connection portion 221b may not be electrically connected to the surface signal portion 221a. It is obvious that the two connection portions 221b may both not be electrically connected to the surface signal portion 221a.

In these optional embodiments, through the above setting, the overlapping area between all pixel electrodes 31 and the constant signal line 22 is further increased, to reduce the possibility of crosstalk between all pixel electrodes and the non-constant signal line 21, and improve the overall display effect of the display panel.

In some optional embodiments, as shown in FIG. 2 to FIG. 5, in the region corresponding to the virtual quadrilateral Q, along the second direction Y, an orthographic projection of at least one of the first electrode 311 and the second electrode 312 on the base 10 overlaps with an orthographic projection of a pattern surrounded and defined by the contour of the via K1 on the base 10.

Optionally, the connection portion 221b may include a first connection portion 221b1 and a second connection portion 221b2, the orthographic projection of the first electrode 311 on the base 10 at least partially overlaps with an orthographic projection of the first connection portion 221b1 on the base 10, and the orthographic projection of the second electrode 312 on the base 10 at least partially overlaps with an orthographic projection of the second connection portion 221b2 on the base 10.

In some embodiments, in the region corresponding to the virtual quadrilateral Q, a portion of the first electrode 311 extends along the second direction Y and toward the centroid of the via K1, so that the first electrode 311 includes a first region, a second region, and a third region, wherein the orthographic projection of the first region on the base 10 is located on a side of the orthographic projection of the first connection portion 221b1 on the base 10 away from the contour of the via K1, the orthographic projection of the second region on the base 10 overlaps with the orthographic projection of the first connection portion 221b1 on the base 10, and the orthographic projection of the third region on the base 10 overlaps with the orthographic projection of the pattern surrounded and defined by the contour of the via K1 on the base 10, and a portion of the orthographic projection of the third region on the base 10 is located within the orthographic projection of the pattern surrounded and defined by the contour of the via K1 on the base 10. The overlapping relationship between the second electrode 312 and the pattern surrounded and defined by the contour of the via K1 is the same as that between the first electrode 311 and the pattern surrounded and defined by the contour of the via K1, and will not be repeated in this embodiment.

In some embodiments, in the region corresponding to the virtual quadrilateral Q, along the second direction Y, the orthographic projections of both the first electrode 311 and the second electrode 312 on the base 10 extend beyond the orthographic projections of the connection portions 221b that overlap with them on the base 10 and overlap with the orthographic projection of the pattern surrounded and defined by the contour of the via K1 on the base 10. In other embodiments, in the region corresponding to the virtual quadrilateral Q, along the second direction Y, the orthographic projection of the first electrode 311 on the base 10 extends beyond the orthographic projection of the first connection portion 221b1 on the base 10 and overlaps with the orthographic projection of the pattern surrounded and defined by the contour of the via K1 on the base 10. In still other embodiments, in the region corresponding to the virtual quadrilateral Q, along the second direction Y, the orthographic projection of the second electrode 312 on the base 10 extends beyond the orthographic projection of the second connection portion 221b2 on the base 10 and overlaps with the orthographic projection of the pattern surrounded and defined by the contour of the via K1 on the base 10.

Through the above setting, this embodiment is conducive to increasing the overlapping area between the first electrode 311 and/or the second electrode 312 and the connection portion 221b, thereby increasing the overlapping area between the first electrode 311 and/or the second electrode 312 and the constant signal line 22, enhancing the capacitive coupling effect between the first electrode 311 and/or the second electrode 312 and the constant signal line 22, reducing the possibility of crosstalk between the pixel electrode 31 and the non-constant signal line 21, and improving the reliability of the display panel.

In some embodiments, as shown in FIG. 5 and FIG. 6, an edge of at least one of the first electrode 311 and the second electrode 312 includes a second edge L2, and at least a portion of an orthographic projection of the second edge L2 on the base 10 is located within the orthographic projection of the pattern surrounded and defined by the contour of the via K1 on the base 10. In some embodiments, the second edge L2 extends along the first direction X.

Under the condition that in the region corresponding to the virtual quadrilateral Q, along the second direction Y, the orthographic projection of the first electrode 311 on the base 10 extends beyond the orthographic projection of the first connection portion 221b1 on the base 10 and overlaps with the orthographic projection of the pattern surrounded and defined by the contour of the via K1 on the base 10, at least a portion of the orthographic projection of the second edge L2 on the base 10 is located within the orthographic projection of the pattern surrounded and defined by the contour of the via K1 on the base 10. The overlapping relationship between the second electrode 312 including the second edge L2 along the second direction Y and the pattern surrounded and defined by the contour of the via K1 is the same as that of the first electrode 311 including the second edge L2 along the second direction Y and the pattern surrounded and defined by the contour of the via K1, or may be different.

Optionally, the orthographic projection of the second edge L2 on the base 10 is entirely located within the orthographic projection of the pattern surrounded and defined by the contour of the via K1 on the base 10.

In some embodiments, the edges of both the first electrode 311 and the second electrode 312 include the second edge L2, the second edge L2 extends along the first direction X, that is, the edges of the first electrode 311 and the second electrode 312 along the second direction Y are both the second edge L2, and at least a portion of the orthographic projection of the second edge L2 on the base 10 is located within the orthographic projection of the pattern surrounded and defined by the contour of the via K1 on the base 10. In other embodiments, the edge of the first electrode 311 along the second direction Y is the second edge L2, and at least a portion of the orthographic projection of the second edge L2 on the base 10 is located within the orthographic projection of the pattern surrounded and defined by the contour of the via K1 on the base 10. In still other embodiments, the edge of the second electrode 312 along the second direction Y is the second edge L2, and at least a portion of the orthographic projection of the second edge L2 on the base 10 is located within the orthographic projection of the pattern surrounded and defined by the contour of the via K1 on the base 10.

In these optional embodiments, by providing the second edge L2, the shielding area of the first electrode 311 and the second electrode 312 on the via K1 in the thickness direction Z is reduced, so that the via can be used as a light-transmitting hole or an avoidance hole for other conductive structures, thereby increasing the overlapping area between the first electrode 311 and the second electrode 312 and the constant signal line 22 while improving the design flexibility of the via K1.

In other embodiments, the edge of the third electrode 313 includes the second edge L2, the second edge L2 extends along the first direction X, that is, the edge of the third electrode 313 along the second direction Y is the second edge L2, thereby reducing the dimension of the third electrode 313 in the second direction Y.

Optionally, the second edge is a straight edge.

In some optional embodiments, as shown in FIG. 8 and FIG. 9, the first electrode 311, the second electrode 312, and the third electrode 313 are sequentially spaced apart and extend along the same direction.

Optionally, as shown in FIG. 9, the first electrode 311, the second electrode 312, and the third electrode 313 may be spaced apart along the second direction Y, and the first electrode 311, the second electrode 312, and the third electrode 313 all extend along the first direction X. Or, as shown in FIG. 8, the first electrode 311, the second electrode 312, and the third electrode 313 may be spaced apart along the first direction X, and the first electrode 311, the second electrode 312, and the third electrode 313 all extend along the second direction Y. It is obvious that the first electrode 311, the second electrode 312, and the third electrode 313 may also be arranged along other directions.

Through the above setting, this embodiment is conducive to simplifying the arrangement of the pixel electrodes 31, thereby reducing the manufacturing difficulty of the pixel electrodes 31 and improving the manufacturing yield of the array substrate 100.

In some optional embodiments, as shown in FIG. 8, an extension direction of each of the constant signal line 22 and the non-constant signal line 21 intersects an extension direction of the first electrode 311, the second electrode 312, and the third electrode 313. Wherein orthographic projections of the first electrode 311, the second electrode 312, and the third electrode 313 on the base 10 are all overlapped with an orthographic projection of the same constant signal line 22 on the base 10; and/or, orthographic projections of the first electrode 311, the second electrode 312, and the third electrode 313 on the base 10 are all overlapped with an orthographic projection of the same non-constant signal line 21 on the base 10.

Optionally, the extension direction of the constant signal line 22 and the non-constant signal line 21 is the first direction X, and the extension direction of the first electrode 311, the second electrode 312, and the third electrode 313 is the second direction Y. Or, the extension direction of the constant signal line 22 and the non-constant signal line 21 is the second direction Y, and the extension direction of the first electrode 311, the second electrode 312, and the third electrode 313 is the first direction X.

In some embodiments, the orthographic projections of the first electrode 311, the second electrode 312, and the third electrode 313 on the base 10 are all overlapped with the orthographic projection of the same constant signal line 22 on the base 10, and the orthographic projections of the first electrode 311, the second electrode 312, and the third electrode 313 on the base 10 are all overlapped with the orthographic projection of the same non-constant signal line 21 on the base 10. In other embodiments, the orthographic projections of the first electrode 311, the second electrode 312, and the third electrode 313 on the base 10 are all overlapped with the orthographic projection of the same constant signal line 22 on the base 10. In still other embodiments, the orthographic projections of the first electrode 311, the second electrode 312, and the third electrode 313 on the base 10 are all overlapped with the orthographic projection of the same non-constant signal line 21 on the base 10.

Optionally, the number of constant signal lines 22 whose orthographic projections on the base 10 overlap with the orthographic projections of the first electrode 311, the second electrode 312, and the third electrode 313 on the base 10 may be one or more. For example, the orthographic projections of multiple constant signal lines 22 on the base 10 all overlap with the orthographic projections of the first electrode 311, the second electrode 312, and the third electrode 313 on the base 10.

Optionally, the number of non-constant signal lines 21 whose orthographic projections on the base 10 overlap with the orthographic projections of the first electrode 311, the second electrode 312, and the third electrode 313 on the base 10 may be one or more. For example, the orthographic projections of multiple non-constant signal lines 21 on the base 10 all overlap with the orthographic projections of the first electrode 311, the second electrode 312, and the third electrode 313 on the base 10.

Through the above setting, this embodiment allows one constant signal line 22 to be arranged below the first electrode 311, the second electrode 312, and the third electrode 313 during wiring, thereby increasing the wiring area of the constant signal line 22 and the overlapping area between the constant signal line and the pixel electrode 31. At the same time, one non-constant signal line 21 can be arranged below the first electrode 311, the second electrode 312, and the third electrode 313 during wiring, which can increase the wiring area of the non-constant signal line 21, increase the design flexibility of the circuit, and improve the application range of the array substrate 100.

In some optional embodiments, the constant signal lines 22 include a first constant signal line 221 and a second constant signal line 222, the non-constant signal line 21s include a first non-constant signal line 211, the first constant signal line 221, the second constant signal line 222, and the first non-constant signal line 211 all extend along the first direction X and are spaced apart along the second direction Y. Wherein one first constant signal line 221 is disposed between any two adjacent lines selected from the first non-constant signal line 211 corresponding to the first electrode 311, the first non-constant signal line 211 corresponding to the second electrode 312, the first non-constant signal line 211 corresponding to the third electrode 313, and the second constant signal line 222.

Exemplarily, the first non-constant signal line 211 corresponding to the first electrode 311, the first non-constant signal line 211 corresponding to the second electrode 312, the first non-constant signal line 211 corresponding to the third electrode 313, and the second constant signal line 222 are spaced apart along the second direction Y in sequence, and one first constant signal line 221 is disposed between the first non-constant signal line 211 corresponding to the first electrode 311 and the first non-constant signal line 211 corresponding to the second electrode 312, one first constant signal line 221 is disposed between the first non-constant signal line 211 corresponding to the second electrode 312 and the first non-constant signal line 211 corresponding to the third electrode 313, and one first constant signal line 221 is disposed between the first non-constant signal line 211 corresponding to the third electrode 313 and the second constant signal line 222.

In some optional embodiments, the orthographic projection of the first non-constant signal line 211 corresponding to the first electrode 311 on the base 10 and the orthographic projection of the second constant signal line 222 on the base 10 are symmetrically arranged about a center line of the orthographic projection of the first electrode 311 on the base 10 along the first direction X; and/or, the orthographic projection of the first non-constant signal line 211 corresponding to the second electrode 312 on the base 10 and the orthographic projection of the first non-constant signal line 211 corresponding to the third electrode 313 on the base 10 are symmetrically arranged about the center line of the orthographic projection of the first electrode 311 on the base 10 along the first direction X.

Optionally, the center line of the first electrode 311 along the first direction X may be the center line of the second electrode 312 along the first direction X, or may be the center line of the third electrode 313 along the first direction X.

In some optional embodiments, the orthographic projections of the first constant signal line 221 corresponding to the first electrode 311, the first constant signal line 221 corresponding to the second electrode 312, and the first constant signal line 221 corresponding to the third electrode 313 on the base 10 are arranged along the second direction Y in sequence, the orthographic projection of the first constant signal line 221 corresponding to the second electrode 312 on the base 10 passes through a center line of the orthographic projection of the first electrode 311 on the base 10 along the first direction X, and is symmetrically arranged about the center line of the orthographic projection of the first electrode 311 on the base 10 along the first direction X. The orthographic projection of the first constant signal line 221 corresponding to the first electrode 311 on the base 10 and the orthographic projection of the first constant signal line 221 corresponding to the third electrode 313 on the base 10 are symmetrically arranged about the center line of the orthographic projection of the first electrode 311 on the base 10 along the first direction X.

Optionally, the light-emitting units 70 corresponding to the first electrode 311, the second electrode 312, and the third electrode 313 may form a pixel unit. Along the second direction Y, a light-transmitting region may be formed between adjacent two pixel units. Optionally, the display panel 200 may include a light-transmitting region, and in the light-transmitting region, the light-transmitting region between adjacent two pixels may be used for light transmission.

In some optional embodiments, as shown in FIG. 9, an extension direction of each of the constant signal line 22 and the non-constant signal line 21 is the same as an extension direction of the first electrode 311, the second electrode 312, and the third electrode 313. Wherein orthographic projections of at least two of the first electrode 311, the second electrode 312, and the third electrode 313 on the base 10 are respectively overlapped with orthographic projections of different constant signal lines 22 on the base 10; and/or, orthographic projections of at least two of the first electrode 311, the second electrode 312, and the third electrode 313 on the base 10 are respectively overlapped with orthographic projections of different non-constant signal lines 21 on the base 10.

Optionally, the extension direction of the constant signal line 22 and the non-constant signal line 21 is the first direction X, and the extension direction of the first electrode 311, the second electrode 312, and the third electrode 313 is the first direction X. Or, the extension direction of the constant signal line 22 and the non-constant signal line 21 is the second direction Y, and the extension direction of the first electrode 311, the second electrode 312, and the third electrode 313 is the second direction Y.

Exemplarily, a plurality of constant signal lines 22 are spaced apart along the second direction Y, and the plurality of constant signal lines 22 along the second direction Y are, in order, a first constant signal line 22, a second constant signal line 22, and a third constant signal line. The first electrode 311, the second electrode 312, and the third electrode 313 are arranged along the second direction Y in sequence. The orthographic projection of the first electrode 311 on the base 10 overlaps with the orthographic projection of the first constant signal line 22 on the base 10, the orthographic projection of the second electrode 312 on the base 10 overlaps with the orthographic projection of the first constant signal line 22 on the base 10, and the orthographic projection of the third electrode 313 on the base 10 overlaps with the orthographic projection of the second constant signal line 22 on the base 10. Or, the orthographic projection of the first electrode 311 on the base 10 overlaps with the orthographic projection of the first constant signal line 22 on the base 10, the orthographic projection of the second electrode 312 on the base 10 overlaps with the orthographic projection of the second constant signal line 22 on the base 10, and the orthographic projection of the third electrode 313 on the base 10 overlaps with the orthographic projection of the second constant signal line 22 on the base 10. Or, the orthographic projection of the first electrode 311 on the base 10 overlaps with the orthographic projection of the first constant signal line 22 on the base 10, the orthographic projection of the second electrode 312 on the base 10 overlaps with the orthographic projection of the second constant signal line 22 on the base 10, and the orthographic projection of the third electrode 313 on the base 10 overlaps with the orthographic projection of the third constant signal line 22 on the base 10.

Exemplarily, a plurality of non-constant signal lines 21 are spaced apart along the second direction Y, and the plurality of non-constant signal lines 21 along the second direction Y are, in order, a first non-constant signal line 21, a second non-constant signal line 21, and a third non-constant signal line. The first electrode 311, the second electrode 312, and the third electrode 313 are arranged along the second direction Y in sequence. The orthographic projection of the first electrode 311 on the base 10 overlaps with the orthographic projection of the first non-constant signal line 21 on the base 10, the orthographic projection of the second electrode 312 on the base 10 overlaps with the orthographic projection of the first non-constant signal line 21 on the base 10, and the orthographic projection of the third electrode 313 on the base 10 overlaps with the orthographic projection of the second non-constant signal line 21 on the base 10. Or, the orthographic projection of the first electrode 311 on the base 10 overlaps with the orthographic projection of the first non-constant signal line 21 on the base 10, the orthographic projection of the second electrode 312 on the base 10 overlaps with the orthographic projection of the second non-constant signal line 21 on the base 10, and the orthographic projection of the third electrode 313 on the base 10 overlaps with the orthographic projection of the second non-constant signal line 21 on the base 10. Or, the orthographic projection of the first electrode 311 on the base 10 overlaps with the orthographic projection of the first non-constant signal line 21 on the base 10, the orthographic projection of the second electrode 312 on the base 10 overlaps with the orthographic projection of the second non-constant signal line 21 on the base 10, and the orthographic projection of the third electrode 313 on the base 10 overlaps with the orthographic projection of the third non-constant signal line 21 on the base 10.

In some embodiments, the orthographic projections of at least two of the first electrode 311, the second electrode 312, and the third electrode 313 on the base 10 are respectively overlapped with the orthographic projections of different constant signal lines 22 on the base 10, and the orthographic projections of at least two of the first electrode 311, the second electrode 312, and the third electrode 313 on the base 10 are respectively overlapped with the orthographic projections of different non-constant signal lines 21 on the base 10. In other embodiments, the orthographic projections of at least two of the first electrode 311, the second electrode 312, and the third electrode 313 on the base 10 are respectively overlapped with the orthographic projections of different constant signal lines 22 on the base 10. In still other embodiments, the orthographic projections of at least two of the first electrode 311, the second electrode 312, and the third electrode 313 on the base 10 are respectively overlapped with the orthographic projections of different non-constant signal lines 21 on the base 10.

Through the above arrangement, this embodiment reduces the dimension of the pixel electrode 31 in the arrangement direction and increases the dimension of the pixel electrode 31 in its own extension direction, thereby increasing the overlapping area between the pixel electrode 31 and a single constant signal line 22 and the overlapping area between the pixel electrode 31 and a single non-constant signal line 21, reducing the capacitive coupling effect between the pixel electrode 31 and different constant signal lines 22, further reducing the possibility of crosstalk between the non-constant signal line 21 and the pixel electrode 31, improving the display effect of the corresponding light-emitting unit 70, and enhancing the reliability of the display panel.

In some optional embodiments, the constant signal line 22s include a first constant signal line 221 and a second constant signal line 222, the non-constant signal lines 21 include a first non-constant signal line 211, the first constant signal line 221, the second constant signal line 222, and the first non-constant signal line 211 all extend along the first direction X and are spaced apart along the second direction Y. Wherein an orthographic projection of the first constant signal line 221 corresponding to the first electrode 311 or the second electrode 312 on the base 10 passes through a center line of an orthographic projection of the first electrode 311 or the second electrode 312 on the base 10 along the first direction X, and is symmetrically arranged about the center line of the orthographic projection of the first electrode 311 or the second electrode 312 on the base 10 along the first direction X.

Exemplarily, the orthographic projection of the first constant signal line 221 corresponding to the first electrode 311 on the base 10 passes through the center line of the orthographic projection of the first electrode 311 on the base 10 along the first direction X, and the orthographic projection of this first constant signal line 221 on the base 10 is symmetrically arranged about the center line of the orthographic projection of the first electrode 311 on the base 10 along the first direction X. And/or, the orthographic projection of the first constant signal line 221 corresponding to the second electrode 312 on the base 10 passes through the center line of the orthographic projection of the second electrode 312 on the base 10 along the first direction X, and the orthographic projection of this first constant signal line 221 on the base 10 is symmetrically arranged about the center line of the orthographic projection of the second electrode 312 on the base 10 along the first direction X.

In some optional embodiments, the orthographic projection of the first non-constant signal line 211 corresponding to the second electrode 312 on the base 10 and an orthographic projection of the second constant signal line 222 overlapped with the orthographic projection of the second electrode 312 on the base 10 are symmetrically arranged about the center line of the orthographic projection of the second electrode 312 on the base 10 along the first direction X.

Exemplarily, the orthographic projection of one second constant signal line 222 on the base 10 overlaps with the orthographic projection of the second electrode 312 on the base 10, and the overlapping portion of the orthographic projection of this second constant signal line 222 on the base 10 and the orthographic projection of the second electrode 312 on the base 10 and the first non-constant signal line 211 corresponding to the second electrode 312 are symmetrically arranged about the center line of the orthographic projection of the second electrode 312 on the base 10 along the first direction X.

In some embodiments, the second constant signal line 222 has a mesh structure. For example, a portion of the plurality of second constant signal lines 222 extends along the first direction X, and another portion of the plurality of second constant signal lines 222 extends along the second direction Y. The second constant signal lines 222 extending along the first direction X are in the same layer as the first constant signal line 221, and the second constant signal lines 222 extending along the second direction Y are in a different layer from the second constant signal lines 222 extending along the first direction X. A via structure may be provided between the second constant signal lines 222 extending along the second direction Y and the second constant signal lines 222 extending along the first direction X. The via structure may be located in the overlapping region between the second constant signal line 222 and the pixel electrode 31. The symmetry of the second constant signal line 222 with other signal lines about the center line of the pixel electrode 31 along the first direction X refers to the extending structure of the second constant signal line 222, excluding the via structure. Similarly, the first non-constant signal line 211 and the first constant signal line 221 may also include via structures. The symmetry of the first non-constant signal line 211 and the first constant signal line 221 with other signal lines about the center line of the orthographic projection of the pixel electrode 31 on the base 10 along the first direction X is the same as that of the second constant signal line 222 with other signal lines.

In some optional embodiments, a distance between the orthographic projection of the first non-constant signal line 211 corresponding to the second electrode 312 on the base 10 and the center line of the orthographic projection of the second electrode 312 on the base 10 along the first direction X is equal to a distance between the orthographic projection of the second constant signal line 222 overlapped with the orthographic projection of the second electrode 312 on the base 10 and the center line of the orthographic projection of the second electrode 312 on the base 10 along the first direction X.

In some optional embodiments, the first constant signal line 221 corresponding to the third electrode 313 includes a first branch line, a second branch line, and a connection line, the first branch line and the second branch line both extend along the first direction X and are spaced apart along the second direction Y, the first branch line and the second branch line are connected through the connection line, and the orthographic projection of the third electrode 313 on the base 10 overlaps with the orthographic projection of the first non-constant signal line 211 for driving the pixel circuit of the first electrode 311 on the base 10. Wherein the orthographic projection of the first branch line on the base 10 passes through a center line of the orthographic projection of the third electrode 313 on the base 10 along the first direction X and is symmetrically arranged about the center line of the orthographic projection of the third electrode 313 on the base 10 along the first direction X, the orthographic projection of the first non-constant signal line 211 corresponding to the third electrode 313 on the base 10 and the orthographic projection of the second branch line on the base 10 are symmetrically arranged about the center line of the orthographic projection of the third electrode 313 on the base 10 along the first direction X, and the orthographic projection of the second constant signal line 222 overlapped with the orthographic projection of the third electrode 313 on the base 10 on the base 10 and the orthographic projection of the first non-constant signal line 211 for driving the pixel circuit of the first electrode 311 on the base 10 are symmetrically arranged about the center line of the orthographic projection of the third electrode 313 on the base 10 along the first direction X.

Optionally, the orthographic projections of one first branch line on the base 10, one second branch line on the base 10, and the connection line on the base 10 all overlap with the orthographic projection of the same third electrode 313 on the base 10. Optionally, one first branch line, one second branch line, and the connection line for connecting the first branch line and the second branch line form a repeating structure. One first constant signal line 221 may include multiple repeating structures. One constant signal line 22 is connected to multiple pixel circuits driving the third electrode 313, and the multiple repeating structures and the multiple third electrodes 313 are arranged in one-to-one correspondence.

Optionally, one first branch line and one second branch line may be connected through one or more connection lines.

Exemplarily, the orthographic projection of the first branch line on the base 10 passes through the center line of the orthographic projection of the third electrode 313 on the base 10 along the first direction X, and the orthographic projection of the first branch line on the base 10 is symmetrically arranged about the center line of the orthographic projection of the third electrode 313 on the base 10 along the first direction X.

Through the above setting, this embodiment is conducive to achieving symmetric arrangement of the signal lines on the side of the third electrode 313 facing the base 10, improving the flatness of the third electrode 313, and reducing the possibility of color shift of the light-emitting unit 70 corresponding to the third electrode 313 at different viewing angles.

In some optional embodiments, an overlapping area between the orthographic projection of the first electrode 311 and the orthographic projection of the first constant signal line 221 on the base 10 is greater than an overlapping area between the orthographic projection of the second electrode 312 and the orthographic projection of the first constant signal line 221 on the base 10, and the overlapping area between the orthographic projection of the second electrode 312 and the orthographic projection of the first constant signal line 221 on the base 10 is greater than an overlapping area between the orthographic projection of the third electrode 313 and the orthographic projection of the first constant signal line 221 on the base 10.

In some optional embodiments, the light-emitting units 70 corresponding to the first electrode 311, the second electrode 312, and the third electrode 313 form a pixel unit. The arrangement of the constant signal line 22 and the non-constant signal line 21 corresponding to the pixel unit is the same as the arrangement of the pixel unit.

Exemplarily, a plurality of pixel units are arranged in an array along the first direction X and the second direction Y. The constant signal line 22 corresponding to the first electrode 311, the non-constant signal line 21 corresponding to the first electrode 311, the constant signal line 22 corresponding to the second electrode 312, the non-constant signal line 21 corresponding to the second electrode 312, the constant signal line 22 corresponding to the third electrode 313, and the non-constant signal line 21 corresponding to the third electrode 313 are arranged as a sub-unit in an array along the first direction X and the second direction Y.

FIG. 10 is another partially enlarged structural diagram of an array substrate 100 according to an embodiment of this application.

In some optional embodiments, as shown in FIG. 10, the first electrode 311 and the second electrode 312 are spaced apart along a first direction X, the third electrode 313 is located on the same side of the first electrode 311 and the second electrode 312 adjacent to the first electrode 311 along a second direction Y, the third electrode 313 is spaced apart from the first electrode 311 and the second electrode 312 adjacent to the first electrode 311 along the second direction Y, and the first direction X, the second direction Y, and a thickness direction Z of the array substrate 100 intersect pairwise.

Exemplarily, the first electrode 311, the second electrode 312, and the third electrode 313 are arranged in a triangular pattern.

Optionally, the area of the third electrode 313 may be greater than or equal to the sum of the areas of the first electrode 311 and the second electrode 312.

Through the above setting, this embodiment is conducive to increasing the arrangement of the corresponding light-emitting units 70, improving the design flexibility of the light-emitting units, and enhancing the application range of the display panel.

In some optional embodiments, the constant signal lines 22 include a first constant signal line 221, the first constant signal line 221 extends along the first direction X. Wherein an overlapping area between an orthographic projection of the first electrode 311 and an orthographic projection of the first constant signal line 221 on the base 10 is less than an overlapping area between an orthographic projection of the second electrode 312 and the orthographic projection of the first constant signal line 221 on the base 10, and the overlapping area between the orthographic projection of the second electrode 312 and the orthographic projection of the first constant signal line 221 on the base 10 is less than an overlapping area between an orthographic projection of the third electrode 313 and the orthographic projection of the first constant signal line 221 on the base 10.

Optionally, the orthographic projection of the first electrode 311 on the base 10 may overlap with the orthographic projection of the first constant signal line 221 for driving the pixel circuit of the first electrode 311 on the base 10. The orthographic projection of the first electrode 311 on the base 10 may also overlap with the orthographic projection of the first constant signal line 221 for driving the pixel circuit of the second electrode 312 on the base 10. It can be understood that under the condition that the orthographic projection of the first electrode 311 on the base 10 overlaps with both the orthographic projection of the first constant signal line 221 for driving the pixel circuit of the first electrode 311 and the orthographic projection of the first constant signal line 221 for driving the pixel circuit of the second electrode 312, the sum of the two overlapping areas is the overlapping area between the first electrode 311 and the first constant signal line 221 on the base 10.

Optionally, the orthographic projection of the second electrode 312 on the base 10 may overlap with the orthographic projection of the first constant signal line 221 for driving the pixel circuit of the second electrode 312 on the base 10. The orthographic projection of the second electrode 312 on the base 10 may also overlap with the orthographic projection of the first constant signal line 221 for driving the pixel circuit of the first electrode 311 on the base 10. It can be understood that under the condition that the orthographic projection of the first electrode 311 on the base 10 overlaps with both the orthographic projection of the first constant signal line 221 for driving the pixel circuit of the first electrode 311 and the orthographic projection of the first constant signal line 221 for driving the pixel circuit of the second electrode 312, the sum of the two overlapping areas is the overlapping area between the second electrode 312 and the first constant signal line 221 on the base 10.

In some optional embodiments, the first constant signal line 221 includes a surface signal portion 221a, an area of the surface signal portion 221a corresponding to the first electrode 311 is equal to an area of the surface signal portion 221a corresponding to the second electrode 312, and the area of the surface signal portion 221a corresponding to the first electrode 311 is less than an area of the surface signal portion 221a corresponding to the third electrode 313.

It can be understood that the area of the surface signal portion 221a corresponding to the second electrode 312 is less than the area of the surface signal portion 221a corresponding to the third electrode 313.

In some optional embodiments, an orthographic projection of a portion of the surface signal portion 221a corresponding to the first electrode 311 on the base 10 overlaps with an orthographic projection of the first electrode 311 on the base 10, and an orthographic projection of another portion of the surface signal portion 221a corresponding to the first electrode 311 on the base 10 overlaps with an orthographic projection of the second electrode 312 on the base 10.

In some optional embodiments, an orthographic projection of the surface signal portion 221a corresponding to the second electrode 312 on the base 10 overlaps with each of orthographic projections of the first electrode 311, the second electrode 312, and the third electrode 313 on the base 10.

Exemplarily, one surface signal portion 221a includes three regions, wherein one region's orthographic projection on the base 10 overlaps with the orthographic projection of the first electrode 311 on the base 10, one region's orthographic projection on the base 10 overlaps with the orthographic projection of the second electrode 312 on the base 10, and the last region's orthographic projection on the base 10 overlaps with the orthographic projection of the third electrode 313 on the base 10.

In some optional embodiments, surface signal portions 221a corresponding to the same type of pixel electrode 31 in adjacent pixel electrodes 31 are connected to form an integral planar structure.

Exemplarily, the surface signal portion 221a corresponding to one third electrode 313 is connected to the surface signal portion 221a corresponding to the third electrode 313 adjacent to this third electrode 313 to form an integral planar structure.

Optionally, one third electrode 313 may correspond to multiple surface signal portions 221a. For example, one third electrode 313 corresponds to two surface signal portions 221a. The area of one of the two surface signal portions 221a corresponding to the third electrode 313 may be greater than the area of the surface signal portion 221a corresponding to the first electrode 311, and the area of the other of the two surface signal portions 221a corresponding to the third electrode 313 may be equal to the area of the surface signal portion 221a that overlaps with the orthographic projection of the first electrode 311 on the base 10 and is configured to drive the pixel circuit of the second electrode 312. And/or, the area of one of the two surface signal portions 221a corresponding to the third electrode 313 may be greater than the area of the surface signal portion 221a corresponding to the second electrode 312, and the area of the other of the two surface signal portions 221a corresponding to the third electrode 313 may be equal to the area of the surface signal portion 221a that overlaps with the orthographic projection of the second electrode 312 on the base 10 and is configured to drive the pixel circuit of the first electrode 311.

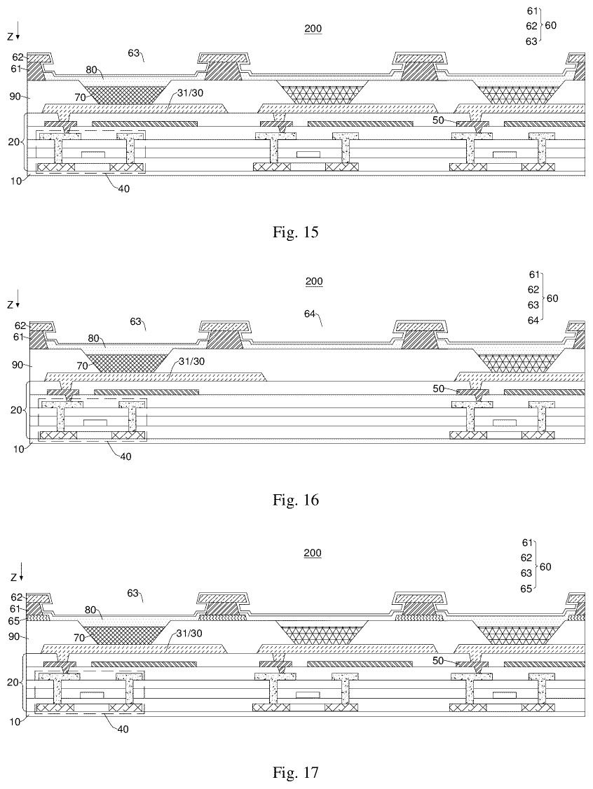

FIG. 15 is a schematic cross-sectional structural diagram of a display panel according to an embodiment of this application.

Please refer to FIG. 15, an embodiment of the third aspect of this application further provides a display panel, including the array substrate 100 according to any of the foregoing embodiments and a light-emitting layer. The light-emitting layer is located on a side of the array substrate 100, and the light-emitting layer includes a light-emitting unit 70, wherein an orthographic projection of the light-emitting unit 70 on the base 10 at least partially overlaps with the orthographic projection of the pixel electrode 31 on the base 10.

Since the display panel provided by the third aspect embodiment of this application includes the array substrate 100 according to any of the foregoing embodiments, the display panel provided by the third aspect embodiment of this application has the beneficial effects of the array substrate 100 according to any of the foregoing embodiments, which will not be repeated here.

In some optional embodiments, as shown in FIG. 15, the display panel further includes an isolation structure 60, the isolation structure 60 is located on a side of the array substrate 100, the isolation structure 60 surrounds and defines an isolation opening 63, and at least a portion of the light-emitting unit 70 is located within the isolation opening 63.

The isolation structure 60 is a structure in the display panel that can isolate different light-emitting units 70.

Optionally, other film layers may be provided between the isolation structure 60 and the first electrode layer 30, and the isolation structure 60 is located on a side of the other film layers away from the first electrode layer 30. Optionally, the other film layers include a pixel definition layer 90. Optionally, the display panel further includes a second electrode layer 80, the second electrode layer 80 is located on a side of the light-emitting unit 70 away from the first electrode layer 30, the second electrode layer 80 may include a plurality of second electrodes, and each second electrode is arranged in one-to-one correspondence with each light-emitting unit 70.

In some optional embodiments, as shown in FIG. 2 to FIG. 4, the isolation structure 60 includes a first isolation portion 61 and a second isolation portion 62 located on a side of the first isolation portion 61 away from the array substrate 100, and an orthographic projection of a side of the first isolation portion 61 away from the array substrate 100 on the base 10 is located within an orthographic projection of the second isolation portion 62 on the base 10.

This design helps in the preparation process of the light-emitting functional layer, making it difficult for the light-emitting material to extend along the sidewall of the first isolation portion 61 to the sidewall of the second isolation portion 62, thereby achieving the preparation and mutual separation of light-emitting units 70 in different isolation openings 63 without the need for a fine metal mask.

This embodiment does not limit the specific structural dimensions of the first isolation portion 61 and the second isolation portion 62. Exemplarily, the longitudinal section (perpendicular to the base) of the isolation structure 60 may have a T-shaped structure.

Compared to the second isolation portion 62, the first isolation portion 61 has a smaller orthographic projection size on the base, and typically, the orthographic projection of the first isolation portion 61 on the base 10 is located at the central position of the orthographic projection of the isolation structure 60 on the base.

In some embodiments, as shown in FIG. 15, an orthographic projection of at least one of the first isolation portion 61 and the second isolation portion 62 on the base 10 partially overlaps with the orthographic projection of the pixel electrode 31 on the base 10.

In some embodiments, the orthographic projections of both the first isolation portion 61 and the second isolation portion 62 on the base 10 partially overlap with the orthographic projection of the pixel electrode 31 on the base 10. In other embodiments, the orthographic projection of the first isolation portion 61 on the base 10 partially overlaps with the orthographic projection of the pixel electrode 31 on the base 10. In still other embodiments, the orthographic projection of the second isolation portion 62 on the base 10 partially overlaps with the orthographic projection of the pixel electrode 31 on the base 10.

FIG. 16 is another schematic cross-sectional structural diagram of a display panel according to an embodiment of this application.

In some embodiments, as shown in FIG. 16, the isolation structure 60 surrounds and defines a first opening 64, and in a direction that the isolation opening 63 and the first opening 64 are arranged side by side, the orthographic projection of the pixel electrode 31 on the base 10 extends beyond an orthographic projection of the isolation structure 60 on the base 10 and overlaps with an orthographic projection of a contour of the first opening 64 on the base 10.

Optionally, the first opening 64 may be a light-transmitting opening, and the first opening 64 can improve the light transmittance of the display panel.

Optionally, the isolation opening 63 and the first opening 64 are spaced apart.

The orthographic projection of the pixel electrode 31 on the base 10 extends beyond the orthographic projection of the isolation structure 60 on the base 10, in other words, a portion of the orthographic projection of the pixel electrode 31 on the base 10 overlaps with the orthographic projection of the isolation opening 63 on the base 10, and another portion of the orthographic projection of the pixel electrode 31 on the base 10 overlaps with the orthographic projection of the first opening 64 on the base 10.

Through the above setting, this embodiment connects the isolation structure 60 to the power supply voltage (e.g., cathode) in the display panel, so that the isolation structure 60 has a constant signal, increases the overlapping area between the pixel electrode 31 and the isolation structure, thereby increasing the design flexibility of the pixel electrode and improving the application range of the display panel.

FIG. 17 is another schematic cross-sectional structural diagram of a display panel according to an embodiment of this application.

As shown in FIG. 17, in some optional embodiments, the isolation structure 60 further includes a third isolation portion 65 located on a side of the first isolation portion 61 toward the array substrate 100. An orthographic projection of the first isolation portion 61 on the base 10 is located within an orthographic projection of the third isolation portion 65 on the base 10.

The third isolation portion 65 is a structure in the isolation structure 60 located on the side of the first isolation portion 61 toward the array substrate 100. The orthographic projection of the first isolation portion 61 on the base 10 is located within the orthographic projection of the third isolation portion 65 on the base 10, that is, in the direction parallel to the plane where the base is located, the third isolation portion 65 can partially extend beyond the first isolation portion 61.

For example, the orthographic projection area of the first isolation portion 61 on the base 10 is smaller than the orthographic projection area of the third isolation portion 65 on the base 10. For example, the longitudinal section (perpendicular to the array substrate 100) of the isolation structure 60 may be I-shaped.

In some optional embodiments, the second electrode layer 80 is electrically connected to the third isolation portion 65, for example, in electrical contact. Limited by the shape structure of the first isolation portion 61, the contact between the second electrode layer 80 and the sidewall of the first isolation portion 61 may be poor. By adding the third isolation portion 65, the second electrode layer 80 can more easily cover a portion of the structure of the third isolation portion 65, that is, the orthographic projection of the second electrode layer 80 on the base 10 can overlap with the orthographic projection of the third isolation portion 65 on the base 10, thereby meeting the electrical connection needs between the second electrode layer 80 and the isolation structure 60. The third isolation portion 65 may include a conductive material. Optionally, the second electrode layer 80 includes a plurality of second pixel electrodes 31, and at least a portion of the plurality of second pixel electrodes 31 is located within the isolation opening 63. Optionally, the second pixel electrode 31 is arranged opposite to the pixel electrode in the first electrode layer 30.

In some optional embodiments, the first isolation portion 61 includes metal, and/or, the second isolation portion 62 includes metal, and/or, the third isolation portion 65 includes metal. Further, the first isolation portion 61 includes aluminum metal, and/or, the second isolation portion 62 includes titanium metal, and/or, the third isolation portion 65 includes molybdenum metal.

In some optional embodiments, the orthographic projection of the pixel electrode 31 on the base 10 at least partially overlaps with the orthographic projection of the third isolation portion 65 on the base 10.

The above specific implementations do not constitute a limitation on the protection scope of this application. Those skilled in the art should understand that, depending on design requirements and other factors, various modifications, combinations, sub-combinations, and substitutions can be made. Any modifications, equivalent replacements, and improvements made within the spirit and principles of this application shall be included within the protection scope of this application.

Although the embodiments disclosed in this application are as above, the content is only to facilitate the understanding of this application and adopted embodiments, and is not intended to limit this application. Any person skilled in the art to which this application belongs may make any modifications and changes in the form and details of implementation without departing from the spirit and scope disclosed in this application, but the protection scope of this application shall still be subject to the scope defined by the appended claims.

The above descriptions are only specific embodiments of this application. Those skilled in the art can clearly understand that, for the convenience and brevity of description, the specific working processes of the above-described systems, modules, and units may refer to the corresponding processes in the foregoing method embodiments and will not be repeated here. It should be understood that the protection scope of this application is not limited thereto. Any person skilled in the art can easily think of various equivalent modifications or substitutions within the technical scope disclosed in this application, and these modifications or substitutions shall be covered within the protection scope of this application.

What is claimed is:

1. An array substrate, comprising:
a base;
a signal line layer group located on a side of the base, wherein the signal line layer group comprises a plurality of non-constant signal lines and a plurality of constant signal lines;
a first electrode layer located on a side of the signal line layer group away from the base, wherein the first electrode layer comprises a plurality of pixel electrodes;
wherein an overlapping area between an orthographic projection of the non-constant signal line and an orthographic projection of one of the pixel electrodes on the base is less than an overlapping area between an orthographic projection of the constant signal line and the orthographic projection of the same one of the pixel electrodes on the base.

2. The array substrate of claim 1, wherein a ratio of the overlapping area between the orthographic projection of the non-constant signal line and the orthographic projection of the pixel electrode on the base to an area of the orthographic projection of the corresponding pixel electrode on the base is S1, and S1≤40%.

3. The array substrate of claim 1, wherein a ratio of the overlapping area between the orthographic projection of the constant signal line and the orthographic projection of the pixel electrode on the base to an area of the orthographic projection of the corresponding pixel electrode on the base is S2, and S2≥45%.

4. The array substrate of claim 1, wherein the pixel electrodes comprise a plurality of first electrodes, a plurality of second electrodes, and a plurality of third electrodes, and the first electrodes, the second electrodes, and the third electrodes are respectively disposed corresponding to light-emitting units of different colors.

5. The array substrate of claim 4, wherein centroids of one of the first electrodes, one of the second electrodes, and two of the third electrodes are respectively disposed at four vertices of a virtual quadrilateral;
wherein in a region corresponding to the virtual quadrilateral, the two of the third electrodes are spaced apart along a first direction, the one of the first electrodes and the one of the second electrodes are spaced apart along a second direction, and the first direction, the second direction, and a thickness direction of the array substrate intersect pairwise.

6. The array substrate of claim 5, wherein the constant signal lines comprise a first constant signal line and a second constant signal line, the non-constant signal lines comprise a first non-constant signal line, and the first constant signal line, the second constant signal line, and the first non-constant signal line all extend along the first direction and are spaced apart along the second direction;
an orthographic projection of at least one of the first constant signal line and the second constant signal line on the base at least overlaps with an orthographic projection of the first electrode on the base, an orthographic projection of at least one of the first constant signal line and the second constant signal line on the base at least overlaps with an orthographic projection of the second electrode on the base, and an orthographic projection of the first non-constant signal line on the base at least overlaps with the orthographic projection of the first electrode on the base and the orthographic projection of the second electrode on the base.

7. The array substrate of claim 6, wherein,
the first constant signal line corresponding to the first electrode or the second electrode is disposed on both sides of the second constant signal line corresponding to the same first electrode or the same second electrode along a width direction of the second constant signal line; or the first non-constant signal line corresponding to the first electrode or the second electrode a is disposed on both sides of the second constant signal line corresponding to the same first electrode or the same second electrode along the width direction of the second constant signal line.

8. The array substrate of claim 7, wherein,
orthographic projections on the base of a plurality of first constant signal lines or a plurality of first non-constant signal lines disposed on both sides of the second constant signal line corresponding to the same first electrode or the same second electrode along a width direction of the second constant signal line are symmetrically arranged about a center line of the orthographic projection of the first electrode on the base along the first direction;
the first non-constant signal line corresponding to the first electrode or the second electrode comprises a first segment and a second segment connected to each other, an orthographic projection of the first segment on the base intersects a center line of the orthographic projection of the first electrode or the second electrode on the base along the second direction, a minimum distance between an orthographic projection of the second segment on the base and an orthographic projection of the second constant signal line adjacent to the second segment on the base is greater than a maximum distance between the orthographic projection of the first segment on the base and an orthographic projection of the second constant signal line adjacent to the first segment on the base;
the orthographic projection of the first segment on the base is parallel to the orthographic projection of the second constant signal line on the base;
the orthographic projection of the second segment on the base is parallel to the orthographic projection of the second constant signal line on the base;
an extension direction of the orthographic projection of the second segment on the base intersects an extension direction of the orthographic projection of the second constant signal line on the base, and a distance between the orthographic projection of the second segment on the base and the orthographic projection of the second constant signal line adjacent to the second segment on the base gradually increases along a direction away from the centroid of the first electrode or the second electrode;
the first non-constant signal line corresponding to the first electrode or the second electrode further comprises a third segment, the third segment is connected to an end of the first segment away from the second segment, a minimum distance between an orthographic projection of the third segment on the base and an orthographic projection of the second constant signal line adjacent to the third segment on the base is greater than a maximum distance between the orthographic projection of the first segment on the base and the orthographic projection of the second constant signal line adjacent to the first segment on the base;
the orthographic projection of the third segment on the base is parallel to the orthographic projection of the second constant signal line on the base;
a distance between the orthographic projection of the third segment on the base and the orthographic projection of the second constant signal line adjacent to the third segment on the base gradually increases along a direction away from the centroid of the orthographic projection of the first electrode or the second electrode on the base;
along the second direction, a distance between the orthographic projection of the second constant signal line corresponding to the first electrode or the second electrode on the base and the orthographic projection of the first non-constant signal line adjacent to the second constant signal line on the base is equal to a distance between the orthographic projection of the first non-constant signal line corresponding to the first electrode or the second electrode on the base and the orthographic projection of the first constant signal line adjacent to the first non-constant signal line on the base.

9. The array substrate of claim 6, wherein the first constant signal line is provided with a via within the region corresponding to the virtual quadrilateral, and the orthographic projection of the pixel electrode on the base at least partially overlaps with an orthographic projection of a contour of the via on the base.

10. The array substrate of claim 9, wherein the first constant signal line comprises a surface signal portion and a connection portion connected to each other within the region corresponding to the virtual quadrilateral, a dimension of the surface signal portion along the second direction is greater than a dimension of the connection portion along the second direction, the surface signal portion and the connection portion surround and define the via, and an orthographic projection of the third electrode on the base at least partially overlaps with an orthographic projection of the surface signal portion on the base;
an orthographic projection of an edge of the surface signal portion on the base is at least partially located within the orthographic projection of the third electrode on the base;
the edge of the surface signal portion comprises a first edge extending along the first direction, and at least a portion of an orthographic projection of the first edge on the base is located within the orthographic projection of the third electrode on the base; and
two surface signal portions are provided within the region corresponding to the virtual quadrilateral, the two surface signal portions are disposed on two sides of the via along the first direction, and the two surface signal portions are disposed in one-to-one correspondence with the two third electrodes.

11. The array substrate of claim 10, wherein an orthographic projection of at least one of the first electrode and the second electrode on the base overlaps with an orthographic projection of the connection portion on the base within the region corresponding to the virtual quadrilateral;
two connection portions are provided within the region corresponding to the virtual quadrilateral, the two connection portions are disposed on two sides of the via along the second direction, an orthographic projection of one of the two connection portions on the base at least partially overlaps with the orthographic projection of the first electrode on the base, and an orthographic projection of the other of the two connection portions on the base at least partially overlaps with the orthographic projection of the second electrode on the base.

12. The array substrate of claim 11, wherein the orthographic projection of at least one of the first electrode and the second electrode on the base overlaps with an orthographic projection of a pattern surrounded and defined by the contour of the via on the base along the second direction within the region corresponding to the virtual quadrilateral;
an edge of at least one of the first electrode and the second electrode comprises a second edge, and at least a portion of an orthographic projection of the second edge on the base is located within the orthographic projection of the pattern surrounded and defined by the contour of the via on the base;
the second edge extends along the first direction; and
the orthographic projection of the second edge on the base is entirely located within the orthographic projection of the pattern surrounded and defined by the contour of the via on the base.

13. The array substrate of claim 9, wherein the array substrate further comprises a thin film transistor, the pixel electrode is electrically connected to the thin film transistor through an electrode connection portion, and orthographic projections of at least a portion of a plurality of the electrode connection portions on the base are located within the orthographic projection of the pattern surrounded and defined by the contour of the via on the base.

14. The array substrate of claim 13, wherein the electrode connection portion comprises a first electrode connection portion and a second electrode connection portion, the first electrode is electrically connected to the thin film transistor through the first electrode connection portion, the second electrode is electrically connected to the thin film transistor through the second electrode connection portion;
an orthographic projection of one of the first electrode connection portion corresponding to the first electrode and the second electrode connection portion corresponding to the second electrode adjacent to the first electrode on the base is located within the orthographic projection of the pattern surrounded and defined by the contour of the via within the virtual quadrilateral on the base, and an orthographic projection of the other on the base is located within an orthographic projection of a pattern surrounded and defined by the contour of the via within another virtual quadrilateral adjacent to the virtual quadrilateral on the base.

15. The array substrate of claim 4, wherein the first electrode, the second electrode, and the third electrode are sequentially spaced apart and extend along the same direction.

16. The array substrate of claim 15, wherein an extension direction of each of the constant signal line and the non-constant signal line intersects an extension direction of the first electrode, the second electrode, and the third electrode;
orthographic projections of the first electrode, the second electrode, and the third electrode on the base are all overlapped with an orthographic projection of the same constant signal line on the base; or the orthographic projections of the first electrode, the second electrode, and the third electrode on the base are all overlapped with an orthographic projection of the same non-constant signal line on the base;
the constant signal lines comprise a first constant signal line and a second constant signal line, the non-constant signal lines comprise a first non-constant signal line, the first constant signal line, the second constant signal line, and the first non-constant signal line all extend along a first direction and are spaced apart along a second direction; wherein one first constant signal line is disposed between any two adjacent lines selected from the first non-constant signal line corresponding to the first electrode, the first non-constant signal line corresponding to the second electrode, the first non-constant signal line corresponding to the third electrode, and the second constant signal line.

17. The array substrate of claim 15, wherein an extension direction of each of the constant signal line and the non-constant signal line is the same as an extension direction of the first electrode, the second electrode, and the third electrode;
orthographic projections of at least two of the first electrode, the second electrode, and the third electrode on the base are respectively overlapped with orthographic projections of different constant signal lines on the base; or orthographic projections of at least two of the first electrode, the second electrode, and the third electrode on the base are respectively overlapped with orthographic projections of different non-constant signal lines on the base;
the constant signal lines comprise a first constant signal line and a second constant signal line, the non-constant signal lines comprise a first non-constant signal line, the first constant signal line, the second constant signal line, and the first non-constant signal line all extend along a first direction and are spaced apart along a second direction; wherein an orthographic projection of the first constant signal line corresponding to the first electrode or the second electrode on the base passes through a center line of an orthographic projection of the first electrode or the second electrode on the base along the first direction, and is symmetrically arranged about the center line of the orthographic projection of the first electrode or the second electrode on the base along the first direction;
an orthographic projection of the first non-constant signal line corresponding to the second electrode on the base and an orthographic projection of the second constant signal line overlapped with the orthographic projection of the second electrode on the base are symmetrically arranged about the center line of the orthographic projection of the second electrode on the base along the first direction; or
a distance between the orthographic projection of the first non-constant signal line corresponding to the second electrode on the base and the center line of the orthographic projection of the second electrode on the base along the first direction is equal to a distance between the orthographic projection of the second constant signal line overlapped with the orthographic projection of the second electrode on the base and the center line of the orthographic projection of the second electrode on the base along the first direction.

18. The array substrate of claim 4, wherein the first electrode and the second electrode are spaced apart along a first direction, the third electrode is located on the same side of the first electrode and the second electrode adjacent to the first electrode along a second direction, the third electrode is spaced apart from the first electrode and the second electrode adjacent to the first electrode along the second direction, and the first direction, the second direction, and a thickness direction of the array substrate intersect pairwise;
the constant signal lines comprise a first constant signal line, the first constant signal line extends along the first direction; wherein an overlapping area between an orthographic projection of the first electrode and an orthographic projection of the first constant signal line on the base is less than an overlapping area between an orthographic projection of the second electrode and the orthographic projection of the first constant signal line on the base, and the overlapping area between the orthographic projection of the second electrode and the orthographic projection of the first constant signal line on the base is less than an overlapping area between an orthographic projection of the third electrode and the orthographic projection of the first constant signal line on the base;
the first constant signal line comprises a surface signal portion, an area of the surface signal portion corresponding to the first electrode is equal to an area of the surface signal portion corresponding to the second electrode, and the area of the surface signal portion corresponding to the first electrode is less than an area of the surface signal portion corresponding to the third electrode;
an orthographic projection of a portion of the surface signal portion corresponding to the first electrode on the base overlaps with an orthographic projection of the first electrode on the base, and an orthographic projection of another portion of the surface signal portion corresponding to the first electrode on the base overlaps with an orthographic projection of the second electrode on the base;
an orthographic projection of the surface signal portion corresponding to the second electrode on the base overlaps with each of orthographic projections of the first electrode, the second electrode, and the third electrode on the base;
surface signal portions corresponding to the same type of pixel electrode in adjacent pixel electrodes are connected to form an integral planar structure.

19. The array substrate of claim 15, wherein the constant signal line comprises a first portion and a second portion connected with each other, a dimension of the first portion along a width direction of the first portion is greater than a dimension of the second portion along a width direction of the second portion, and an orthographic projection of the first portion on the base at least partially overlaps with the orthographic projection of the pixel electrode on the base.

20. The array substrate of claim 1, wherein the constant signal line and the non-constant signal line are disposed in the same layer.

21. The array substrate of claim 1, wherein a distance between the pixel electrode and the non-constant signal line is greater than a distance between the pixel electrode and the constant signal line;
the non-constant signal line is located between the constant signal line and the base.

22. The array substrate of claim 1, wherein a shielding structure is disposed between the non-constant signal line and the pixel electrode, and the shielding structure is electrically connected to a constant voltage terminal.

23. The array substrate of claim 1, wherein a first insulation portion is disposed between the non-constant signal line and the pixel electrode, a second insulation portion is disposed between the constant signal line and the pixel electrode, and a dielectric constant of the first insulation portion is less than a dielectric constant of the second insulation portion.

24. The array substrate of claim 20, wherein a capacitance between the non-constant signal line and the pixel electrode is less than a capacitance between the constant signal line and the pixel electrode.

25. An array substrate, comprising:
a base;
a signal line layer group located on a side of the base, wherein the signal line layer group comprises a plurality of non-constant signal lines and a plurality of constant signal lines, both of the non-constant signal lines and the constant signal lines extend along a first direction;
a first electrode layer located on a side of the signal line layer group away from the base, wherein the first electrode layer comprises a plurality of pixel electrodes;
wherein in a second direction intersecting the first direction,
at least a portion of an orthographic projection of the constant signal line on the base is located within an orthographic projection of one of the pixel electrodes on the base, and at least a portion of an orthographic projection of an edge of the constant signal line away from a centroid of the pixel electrode on the base is located within the orthographic projection of the corresponding pixel electrode on the base.

26. The array substrate of claim 25, wherein a distance between adjacent two pixel electrodes along the second direction is D, a minimum distance between the orthographic projection of the edge of the constant signal line away from the centroid of the pixel electrode on the base and an orthographic projection of an edge of the pixel electrode extending along the first direction is d, and D and d satisfy the relationship: 0.05≤d/D≤0.5.

27. The array substrate of claim 25, wherein the pixel electrodes comprise a first electrode, a second electrode, and a third electrode, and the first electrode, the second electrode, and the third electrode are respectively disposed corresponding to light-emitting units of different colors; the first electrode, the second electrode, and the third electrode are sequentially spaced apart and extend along the same direction;
an extension direction of each of the constant signal line and the non-constant signal line intersects an extension direction of the first electrode, the second electrode, and the third electrode;
orthographic projections of the first electrode, the second electrode, and the third electrode on the base are all overlapped with an orthographic projection of the same constant signal line on the base; the orthographic projections of the first electrode, the second electrode, and the third electrode on the base are all overlapped with an orthographic projection of the same non-constant signal line on the base.

28. The array substrate of claim 25, wherein the pixel electrodes comprise a first electrode, a second electrode, and a third electrode, and the first electrode, the second electrode, and the third electrode are respectively disposed corresponding to light-emitting units of different colors; wherein the first electrode and the second electrode are spaced apart along a first direction, the third electrode is located on the same side of the first electrode and the second electrode adjacent to the first electrode along a second direction, the third electrode is spaced apart from the first electrode and the second electrode adjacent to the first electrode along the second direction, and the first direction, the second direction, and a thickness direction of the array substrate intersect pairwise;
the constant signal lines comprise a first constant signal line, the first constant signal line extends along the first direction; wherein an overlapping area between an orthographic projection of the first electrode and an orthographic projection of the first constant signal line on the base is less than an overlapping area between an orthographic projection of the second electrode and the orthographic projection of the first constant signal line on the base, and the overlapping area between the orthographic projection of the second electrode and the orthographic projection of the first constant signal line on the base is less than an overlapping area between an orthographic projection of the third electrode and the orthographic projection of the first constant signal line on the base;
the first constant signal line comprises a surface signal portion, an area of the surface signal portion corresponding to the first electrode is equal to an area of the surface signal portion corresponding to the second electrode, and the area of the surface signal portion corresponding to the first electrode is less than an area of the surface signal portion corresponding to the third electrode;
an orthographic projection of a portion of the surface signal portion corresponding to the first electrode on the base overlaps with an orthographic projection of the first electrode on the base, and an orthographic projection of another portion of the surface signal portion corresponding to the first electrode on the base overlaps with an orthographic projection of the second electrode on the base;
an orthographic projection of the surface signal portion corresponding to the second electrode on the base overlaps with each of orthographic projections of the first electrode, the second electrode, and the third electrode on the base;
surface signal portions corresponding to the same type of pixel electrode in adjacent pixel electrodes are connected to form an integral planar structure.

29. A display panel, comprising the array substrate of claim 1;
a light-emitting layer located on a side of the array substrate, wherein the light-emitting layer comprises a light-emitting unit, and an orthographic projection of the light-emitting unit on the base at least partially overlaps with the orthographic projection of the pixel electrode on the base.

30. The display panel of claim 29, further comprising an isolation structure, wherein the isolation structure is located on a side of the array substrate, the isolation structure surrounds and defines an isolation opening, and at least a portion of the light-emitting unit is located within the isolation opening;
the isolation structure comprises a first isolation portion and a second isolation portion located on a side of the first isolation portion away from the array substrate, and an orthographic projection of a side of the first isolation portion away from the array substrate on the base is located within an orthographic projection of the second isolation portion on the base;
an orthographic projection of at least one of the first isolation portion and the second isolation portion on the base partially overlaps with the orthographic projection of the pixel electrode on the base;
the isolation structure surrounds and defines a first opening, and in a direction that the isolation opening and the first opening are arranged side by side, the orthographic projection of the pixel electrode on the base extends beyond an orthographic projection of the isolation structure on the base and overlaps with an orthographic projection of a contour of the first opening on the base.
